(19) United States
(12) Patent Application Publication
(10) Pub. No.: US 2026/0052778 A1
(43) Pub. Date: Feb. 19, 2026

(54) LDMOS WITH BIAS CIRCUIT FOR BIASED FIELD PLATE

(71) Applicant: Texas Instruments Incorporated, Dallas, TX (US)

(72) Inventors: Henry Litzmann Edwards, GARLAND, TX (US); Orlando Lazaro, Cary, NC (US); Pavol Balaz, Cupertino, CA (US); Kevin Scoones, San Jose, CA (US); Timothy Merkin, Princeton, TX (US)

(21) Appl. No.: 18/901,069

(22) Filed: Sep. 30, 2024

Related U.S. Application Data
(60) Provisional application No. 63/684,328, filed on Aug. 16, 2024.
(60) Provisional application No. 63/685,424, filed on Aug. 21, 2024.

(51) Int. Cl. H01L 27/02; H01L 29/40; H01L 29/78

(52) U.S. Cl. CPC H10D 89/215; H10D 30/65; H10D 64/111

(57) ABSTRACT

A semiconductor device includes a drain extended transistor with a semiconductor layer including oppositely doped body and drain drift regions, a gate dielectric layer over the body region and extending over a junction between the body region and the drain drift region, a gate electrode over the gate dielectric layer, a drain region in the drain drift region and having a dopant density greater than a dopant density of the drain drift region, and a field plate between the gate electrode and the drain region, and a bias circuit including an output coupled to the field plate and a bias input coupled to a gate drive circuit.

### CROSS-REFERENCE TO RELATED APPLICATION

This application claims priority to and benefit of U.S. Provisional Patent Application Ser. No. 63/684,328, filed on Aug. 16, 2024, and titled “DRAIN EXTENDED TRANSISTOR WITH FIELD PLATES”, and U.S. Provisional Patent Application Ser. No. 63/685,424, filed on Aug. 21, 2024, and titled “DRAIN EXTENDED TRANSISTOR WITH FIELD PLATES”, the contents of which are hereby fully incorporated by reference in their entireties.

### BACKGROUND

Drain extended transistors are used in high voltage applications that require high breakdown voltage ratings and efficient operation, such as a low side switch in a switching power supply to provide low drain-source resistance (RDSON) during the on-state, along with the ability to block or withstand high off-state voltages between the drain and the source or gate. The extended drain architecture has a lightly doped drift region that allows carrier depletion under drain reverse bias so that the drain can block current flow during high voltage operation. The polysilicon gate can be extended across a field relief oxide above the drift region to improve drift region charge balance. However, this approach leaves a nonuniform electric field with peaks in the drift region during off-state operation, such as a peak under the end of the polysilicon field plate. The non-uniform electric field reduces the breakdown voltage from an ideal value and can lead to sub-optimal breakdown voltage performance that can only be addressed by increasing the lateral drift region length to accommodate a required drain blocking voltage in the off state within the limits of semiconductor breakdown strength. Increasing the drift region length to help voltage breakdown performance inhibits efforts to reduce circuit area and increases the on-state drain-source resistance (RDSON) of the transistor as the carriers have more material to travel through.

### SUMMARY

In one aspect, a semiconductor device includes a drain extended transistor, including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region and a field plate between the gate electrode and the drain region, and a bias circuit including an output coupled to the field plate and a bias input coupled to a gate drive circuit.

In another aspect, a semiconductor device includes a drain extended transistor, including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, and a field plate between the gate electrode and the drain region, a bias circuit including a clamp circuit with a diode coupled to the field plate.

In another aspect, a semiconductor device includes a drain extended transistor, including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, and a field plate between the gate electrode and the drain region, and a bias circuit coupled to the field plate, the bias circuit including a reset circuit.

In another aspect, a semiconductor device includes a drain extended transistor, including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, and a field plate between the gate electrode and the drain region, and a bias circuit coupled to the field plate, the bias circuit including a second transistor.

In another aspect, a semiconductor device includes a drain extended transistor, including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, and at least one field plate between the gate electrode and the drain region, and a bias circuit having outputs coupled to the respective field plates, and an input coupled to one of a voltage input of the semiconductor device, the drain region, and a gate drive circuit.

In a further aspect, a method includes forming a drain extended transistor in a semiconductor device, the drain extended transistor including a semiconductor layer including a body region having a first conductivity type and a drain drift region having a second, opposite, conductivity type, a gate dielectric layer over the body region and extending over a junction between the body region and the drain drift region, a gate electrode over the gate dielectric layer;
a drain region having the second conductivity type in the drain drift region, the drain region having a dopant density greater than a dopant density of the drain drift region, and a field plate between the gate electrode and the drain region, and forming a bias circuit in the semiconductor device, the bias circuit including an output coupled to the field plate and a bias input coupled to a gate drive circuit.

### BRIEF DESCRIPTION OF THE DRAWINGS

FIG. 1 is a partial sectional side elevation view of a semiconductor device including a drain extended transistor with a biased field plate taken along line 1-1 in FIG. 1A.

FIG. 1A is a partial top plan view of the semiconductor device of FIG. 1.

FIG. 2 is a partial sectional side elevation view of another semiconductor device including a drain extended transistor with three biased field plates.

FIGS. 3-16 show example bias circuits for providing one or more field plate bias voltages.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”. Unless otherwise stated, “about,” “approximately,” or “substantially” preceding a value means +/−10 percent of the stated value.

One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, components, etc., for ease of description in connection with a particular drawing, where such are not to be construed as limiting with respect to the claims. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

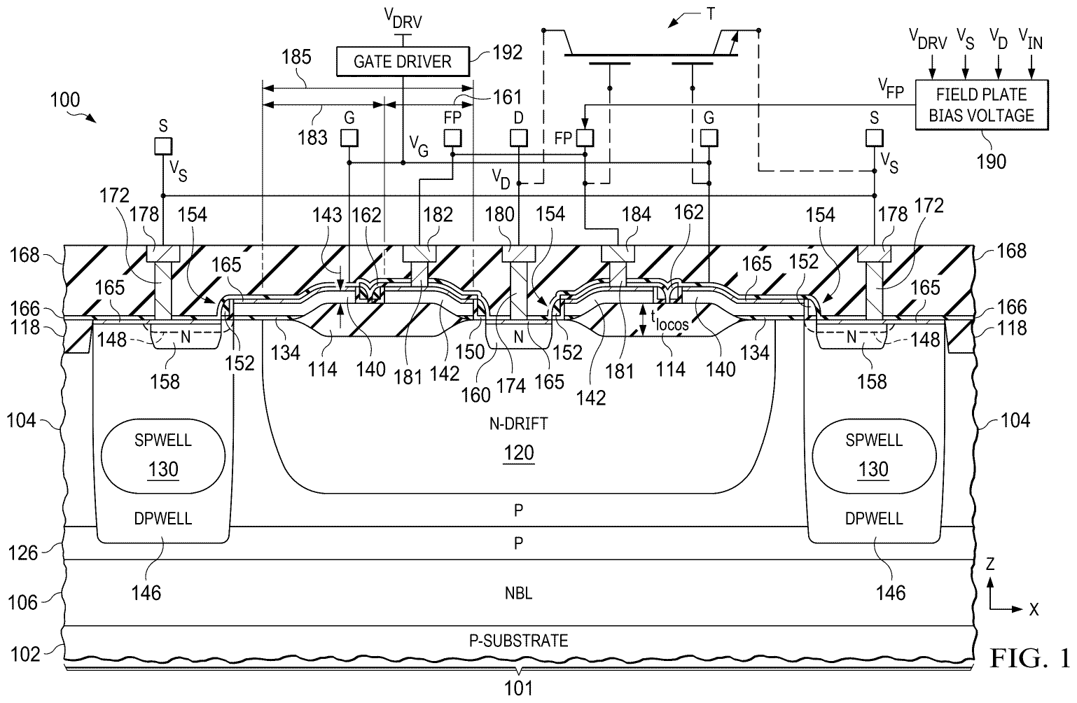

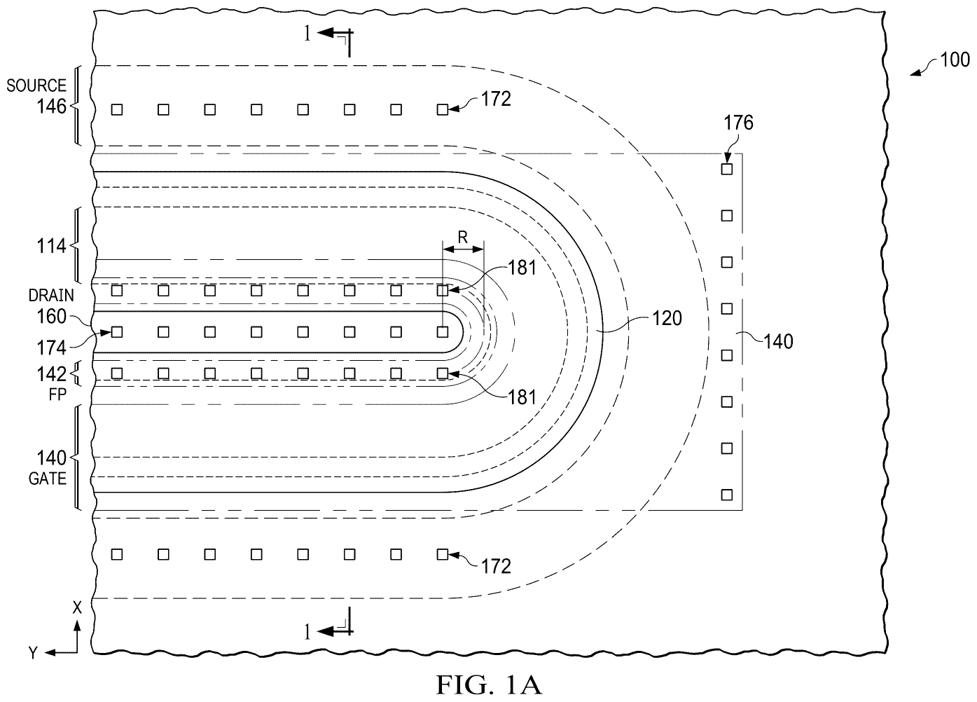

FIGS. 1 and 1A show a semiconductor device 100 that includes a drain extended transistor 101 with a biased field plate 142 having a lateral position and bias voltage determined by device model adjustment through simulation. The biased field plate 142 may also be referred to as a biased drain field plate. Described examples can enable improved off-state drift region electric field profile uniformity while maintaining good breakdown voltage performance with small half pitch dimensions without increasing the drift region length while maintaining low on-state resistance. Although scaling half pitch dimensions may be limited along the drift region by semiconductor breakdown strength and reducing the on-state resistance may be limited by the doping density and carrier mobility in the drift region, field plate positioning and biasing can be tailored for a given design specification through simulation and iterative model adjustment to provide benefits beyond the performance of a gate voltage biased field plate.

The semiconductor device 100 is shown in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The example drain extended transistor 101 is an n-channel laterally diffused metal oxide semiconductor (LDMOS) transistor. FIG. 1 shows a schematic representation of the drain extended transistor 101 labeled “T” with indicated connections to a gate G, a drain D and a source S as well as a field plate FP laterally disposed between the gate G and the drain D. In another implementation, p-channel LDMOS transistors can be formed when n-doped regions are substituted by p-doped regions and p-doped regions are substituted by n-doped regions in another implementation. In one example, further electronic components (not shown) may be provided in the semiconductor device 100, such as a second drain extended transistor interconnected with the illustrated transistor 101 in a half bridge circuit in a packaged integrated circuit with terminals or leads providing external connections to some or all of the transistor terminals. In some implementations, further circuitry can be included, such as gate driver circuits (not shown), switching control timing circuitry, etc., in a single integrated circuit for use in high voltage switching applications such as power conversion systems, transceivers, etc.

As further shown in FIG. 1, the example semiconductor device 100 includes a semiconductor substrate 102, such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon on insulator (SOI) wafer, etc. The semiconductor device 100 in one example includes a semiconductor layer 104 (e.g., p-type epitaxial silicon) that extends over the semiconductor substrate 102 and includes a body region 104 having the first conductivity type (e.g., P-type), where the semiconductor layer 104 may be interchangeably referred to as the body region 104. A n-type buried layer (NBL) 106 extends under the semiconductor layer 104 and has an opposite second conductivity type (e.g., N-type). The device 100 includes a field relief dielectric layer 114, such as a local oxidation of silicon (LOCOS) layer of silicon dioxide (SiO₂). In one example, an isolation structure including shallow trench isolation 118 extends around the outer periphery of the transistor 101 along and into the top side of the semiconductor layer 104.

The semiconductor device 100 includes a drain drift region 120 (e.g., labelled “N-DRIFT” in FIG. 1) having the second conductivity type and extending in the body region 104. The field relief dielectric layer 114 extends over the drain drift region 120. As shown in FIG. 1A, the example drain extended transistor has a finger or racetrack shape with a center drain finger (e.g., labelled “D” in FIG. 1 and “DRAIN” in FIG. 1A), a polysilicon gate (e.g., labelled “G” in FIG. 1 and “GATE” in FIG. 1A) that encircles the drain, and a source (e.g., labelled “S” in FIG. 1 and “SOURCE” in FIG. 1A) that encircles the gate. In this or other examples, the transistor can include further drain-centered finger or racetrack structures (not shown). In these or other implementations, the transistor can include one or more source-centered finger or racetrack structures and/or one or more gate-centered finger or racetrack structures (not shown).

As further shown in FIG. 1, the example semiconductor device 100 can also include a p-type buried layer 126 (e.g., labelled “P”, also referred to as a pRESURF layer for safe operating area (SOA) improvement) with the first conductivity type and a dopant concentration greater than the body region 104. In one example, the body region 104 of the semiconductor layer includes a shallow well 130 (e.g., labeled “SPWELL” in FIG. 1) below the source S, with the first conductivity type (e.g., p-type) and a dopant density higher than that of the body region 104. The shallow well 130 increases a base doping level of the body region 104 to help suppress a parasitic lateral NPN bipolar transistor formed by an N+source-p-body-N+drain D, which may limit high current operation for the LDMOS transistor 101, thus restricting the safe operating area (SOA) of the LDMOS transistor 101.

The transistor 101 also includes a gate dielectric layer 134 with a racetrack shape (FIG. 1A) that extends over a portion of the body region 104 (FIG. 1). The gate dielectric layer 134 extends over a junction between the body region 104 and the drain drift region 120. The gate dielectric layer 134 in one example extends to outer bird's beak tapered portions of the field relief dielectric layer 114 and over the channel and an interface or junction between the p-type body region 104 and the n-type drift region 120 underneath a portion of the gate fingers or racetrack G. As further shown in FIGS. 1 and 1A, a polysilicon gate electrode 140 extends over the gate dielectric layer 134 and also over a portion of the field relief dielectric layer 114 above the drift region 120.

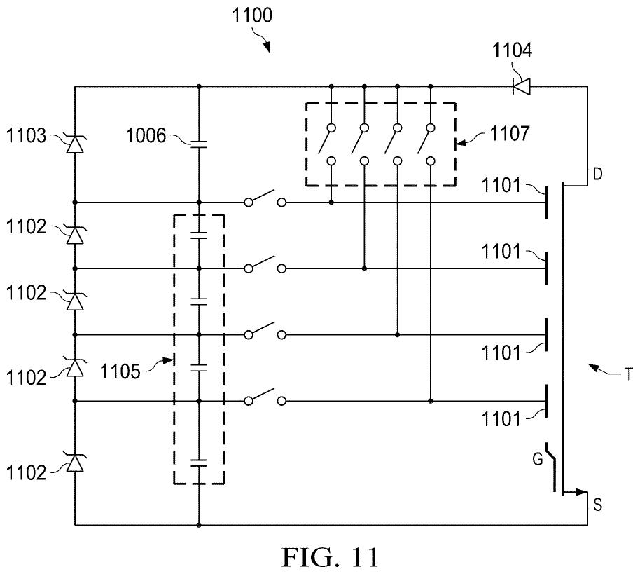

The transistor 101 has a biased field plate 142, which may also be referred to as a biased drain field plate, which is located over the field relief dielectric layer 114. In another implementation, the field relief dielectric layer 114 can be omitted, and the biased field plate 142 is located over the gate dielectric layer 134. The biased field plate 142 in this example also has a racetrack shape (e.g., labelled “FP” in FIGS. 1 and 1A). The biased field plate 142 is laterally spaced apart from the gate electrode 140 and is positioned laterally between the gate electrode 140 and the transistor drain. The field plate 142 is conductively connected to a biasing circuit (not shown) that provides a field plate bias voltage to the field plate 142 in powered operation of the semiconductor device 100. The illustrated example includes a single biased field plate 142. In other implementations (e.g., FIG. 11 below), two or more biased field plates can be provided that are spaced apart from one another and positioned laterally between the gate G and the drain D, with corresponding field plate dimensions and positions as well as field plate bias voltages determined according to an adjusted device model as described further below.

As shown in the example of FIG. 1A, the biased field plate 142 follows a path that has rounded corners with a radius R greater than a thickness 143 (e.g., along the third direction Z in FIG. 1) of the field plate 142. The field relief dielectric layer 114 in one example includes a local oxidation of silicon (LOCOS) layer of silicon dioxide, and the field plate 142 extends over a tapered edge of the field relief dielectric layer 114. In the illustrated example, the field plate 142 is located over a point (e.g., along the first direction X in FIG. 1) at which the LOCOS layer ends (e.g., where a bird's beak shape of the LOCOS field relief dielectric layer 114 begins) at a top surface of the semiconductor layer 104. In one example, the field plate 142 is or includes polycrystalline silicon and can be formed and patterned concurrently with the gate electrode 140.

The example drain extended transistor 101 also includes a source with a p-type deep well region 146 having the first conductivity type (e.g., labelled “DPWELL” in FIG. 1) that extends through and below the p-type shallow well 130. The p-type deep well region 146 extends to the top side of the body region 104 and connects to the p-type buried layer 126. An n-type well region 148 extends along the top side of the p-type deep well region 146 and has the second conductivity type. The example semiconductor device 100 also includes sidewall spacers 154 along the lateral sides of the gate electrode 140 and the field plate 142. The sidewall spacers 154 in one example include an oxide layer 150 and a nitride layer 152 formed by deposition and anisotropic etching. The sidewall spacers 154 overlap an edge of the field relief dielectric layer 114 adjacent to the drain region. In another example, a nitride layer 152 may be deposited across the surface of the wafer and etched to form a nitride-only sidewall spacer 154. The transistor 101 has a source region 158 with the second conductivity type (N-type) in the p-type deep well 146, where the source region 158 has a larger depth than the n-type well region 148.

The transistor drain includes a drain region 160 with the second conductivity type (N-type) extending along and into the top side of the drain drift region 120 in the body region 104 and the drain region 160 is laterally encircled by the field plate 142. The field plate 142 is spaced apart from, and extends laterally between, the gate electrode 140 and the drain region 160. The drain region 160 has a dopant density greater than the dopant density of the drain drift region 120. The field relief dielectric layer 114 extends from the gate dielectric layer 134 toward the drain region 160 and has a thickness greater than the gate dielectric layer 134. The field plate 142 in one example is electrically biased at a non-zero field plate bias voltage with respect to the substrate 102 or with respect to the source. In one example, the field plate 142 extends laterally between the drain region 160 and the gate by a field plate width dimension 161 (FIG. 1) that is at least twice the thickness along the third direction Z of the field relief dielectric layer 114 in one example. In the illustrated example, the field plate 142 extends on a thin bird's beak and of the field relief dielectric layer 114, although not a requirement of all possible implementations. As shown in FIG. 11 below, for example, one or more field plates can extend partially or entirely over portions of the field relief dielectric layer in other implementations.

The semiconductor device 100 in one example has a silicide blocking layer 162 (FIG. 1) that is or includes one or more sublayers of an oxide, a nitride, an oxynitride, or combinations thereof. The silicide blocking layer 162 in one example extends over the sidewall spacers 154 between the gate G and the biased field plate FP. In the illustrated example, the gate electrode 140 extends over the field relief dielectric layer 114 and the gate electrode 140 is laterally spaced apart from the field plate 142 by a portion of the silicide blocking layer 162 that extends on the sidewall spacers 154. The sidewall spacer on the sidewall of the field plate 142 extends to the drain region 160.

The semiconductor device 100 also includes a metal silicide layer 165 that extend along upper sides of the deep well region 146 of the source and of the drain region 160 to facilitate low resistance electrical connection to the source and drain terminals of the transistor 101. In addition, a metal silicide layer 165 can be provided for low resistance electrical connection to the biased field plate 142 and to the gate electrode 140 by conductive metal (e.g., tungsten) contacts including gate contacts in a gate contact region at the lateral ends of the finger structure (FIG. 1A). The semiconductor device 100 also includes a nitride etch stop layer 166 that extends over portions of the metal silicide layer 165, the sidewall spacers 154, and the silicide blocking layer 162.

The semiconductor device 100 can include a single or multilevel metallization structure, with a pre-metal dielectric 168 (PMD), conductive metal (e.g., tungsten) contacts 172 and 174 for the source and the drain (FIGS. 1 and 1A), gate contacts 176 (FIG. 1A), and field plate contacts 181 (FIGS. 1 and 1A). The illustrated portion of the metallization structure in FIG. 1 also shows metal interconnects 178 and 180 conductively coupled to the respective source and drain contacts 172 and 174, as well as metal interconnects 182 and 184 coupled to the field plate contacts 181, and similar metal interconnects (not shown) are coupled to the gate contacts 176 for electrical connection to the various terminals of the transistor 101 in the metallization structure. The metal interconnects 182 and 184 allow electrical connection of a bias voltage circuit (not shown) to bias the field plates 142 and a non-zero field plate bias voltage may be applied during operation of the semiconductor device 100.

The extended drain of the transistor 101 provides a relatively lightly doped drift region to extend the high voltage drain away from the edge of the channel region and the planar drift region can be used to increase the reverse blocking voltage beyond the voltage rating of the gate dielectric layer 134 in a particular process. For even higher drain voltage rating, the drain side of the gate polysilicon is spaced from the drift region 120 by the field relief dielectric layer 114 to facilitate more complete depletion of the drift region. Reduced surface field (RESURF) profiled doping can be used for full reverse bias depletion of the drift region. The drift region doping level or dopant concentration in certain examples can be higher near the connection to the transistor channel region to mitigate channel hot carrier injection into the gate and enhance the transistor reliability. In addition, the biased field plate 142 facilitates enhanced uniformity of the electric field in the drift region 120 below the field relief dielectric layer 114 in the off-state of the transistor 101 to facilitate good breakdown voltage performance of the transistor 101 without adversely impacting the on-state drain-source resistance and without having to increase the lateral length of the drift region along the first direction X.

The semiconductor device 100 in one example includes a field plate voltage bias circuit 190 (FIG. 1) that is configured when the semiconductor device 100 is powered and operating to provide a non-zero field plate bias voltage VFP to the field plate 142 that is different from the voltage of the gate electrode 140. Other implementations can include more than one biased field plate position between the gate and the drain, which are individually biased with different field plate bias voltages that are different from the gate voltage. In one example, a biasing circuit provides the respective field plate bias voltages to maintain monotonic voltage increase of the field plate segments in the direction from the source to the drain such that the field plates shape the potential in the drift region 120 to fall approximately uniformly from drain to source, although not a requirement of all possible implementations.

Any suitable bias circuit 190 can be used for single or multiple biased field plate implementations, for example, a string of diodes connected in series with one another such as Zener diodes, source/drain-to-well diodes, lateral avalanche diodes, diode-connected bipolars, etc. (not shown). In other implementations passive (e.g., resistor based circuitry) and/or active (e.g., diode-connected transistors) may be used to bias the field plate 142 and/or a string of such circuits can be used to bias multiple field plates 142, for example to engineer temperature coefficient matching. In certain implementations (not shown), the bias circuit 190 can include a bias source applied to a diode before the first field plate 142 (nearest the gate) and back-to-back diodes may be added between the last field plate 142 and the drain, permitting the entire string of field plates to be biased during the transistor on-state, reducing RDSON.

In this or another example, the diode before the first field plate 142 nearest the gate may be connected to the gate or to the source or other suitable voltage supply node for simplicity if elevated on-state field plate biasing is not desired. In various implementations, the number of field plates may be varied to choose the drain voltage rating of the device, and the biasing of the field plate facilitates high breakdown voltage rating without having to increase the half pitch of the transistor 101. In multiple field plate implementations, moreover, the field plate width and spacing may be the same, although not a requirement of all possible implementations. In addition, the field plate-to-field plate voltage drops may be approximately equal, although not a requirement of all possible implementations.

In operation, the extended drain of the transistor 101 provides a relatively lightly doped drift region to extend the high voltage drain away from the edge of the channel region and the planar drift region can be used to increase the reverse blocking voltage. For even higher drain voltage rating, the drain side of the gate polysilicon is spaced from the drift region 120 by the gate dielectric layer 134 to facilitate more complete depletion of the drift region. Reduced surface field (RESURF) profiled doping can be used for full reverse bias depletion of the drift region. The drift region doping level or dopant concentration in certain examples can be higher near the connection to the transistor channel region to mitigate channel hot carrier injection into the gate and enhance the transistor reliability. In addition, the biased field plate 142 facilitates enhanced uniformity of the electric field in the drift region 120 below the gate dielectric layer 134 in the off-state of the transistor 101 to facilitate good breakdown voltage performance of the transistor 101 without adversely impacting the on-state drain-source resistance and without having to increase the lateral length of the drift region along the first direction X.

In power switching circuits, such as DC-DC converters, a high-side switch and a low-side switch may be fabricated as drain extended transistors and a source/back gate terminal of the high-side device can be isolated from circuit ground to facilitate high-voltage operation. In addition, shrinking geometries and alignment tolerances of advanced semiconductor manufacturing processes increase the performance impact of non-uniformities such as center-edge differences in device structure locations. Scaling drain extended transistors to reduce the half pitch dimension along the first direction X and/or design of transistors with a fixed half pitch dimension to facilitate higher breakdown voltage ratings can inhibit the ability to balance off-state breakdown voltage performance with low on-state drain-source resistance.

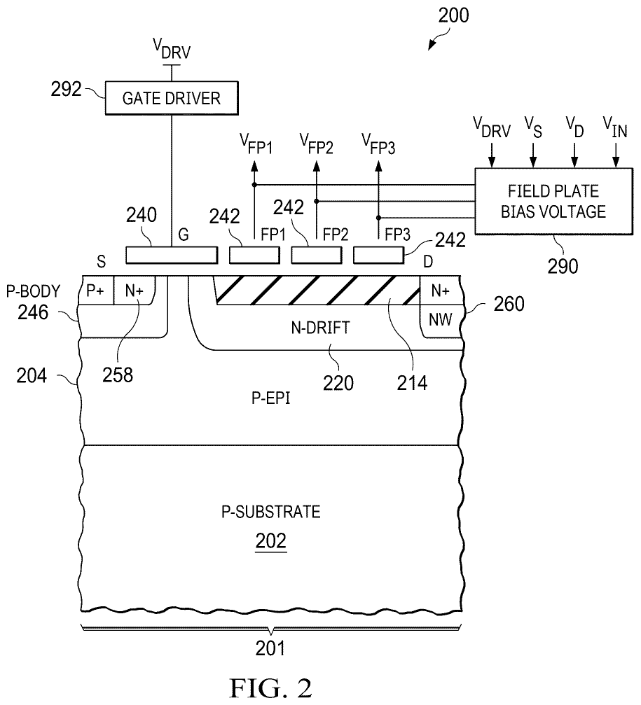

FIG. 2 shows another example semiconductor device 200 that includes a drain extended transistor 201 with three biased field plates 242 (e.g., labeled FP1, FP2, and FP3) spaced apart from one another between a gate electrode 240 and the transistor drain D. The device 200 in FIG. 2 includes a p-substrate 202, a body region with p-type epitaxial silicon 204, a p-type implanted body region 246, an n-type drift region 220, as well as a drain 260 and a source S with an implanted region 258, which can be similar in some respects to the respective structures 142, 140, 102, 104, 146, 120, 160, and 158 as illustrated and described above in connection with FIGS. 1 and 1A. In other implementations, any integer number of biased field plates can be used, with corresponding field plate bias voltages to enhance the uniformity of electric field effects during off-state operation of a drain extended transistor, without significantly adversely impacting the desired low on-state resistance (RDSON) and without requiring increase in the half pitch or other dimensions of the drain extended transistor to facilitate high power density and small form factor electronic devices. In the illustrated example, the field plates 242 are located over the field relief dielectric layer 214. In another implementation, the field relief dielectric layer 214 can be omitted, a thin gate dielectric layer extends under the gate electrode 240 and the field plates 242, with the biased field plates 142 located over the gate dielectric layer.

The semiconductor device 200 in one example includes a field plate voltage bias circuit 290 (FIG. 2) that is configured when the semiconductor device 200 is powered and operating to provide non-zero field plate bias voltages VFP1, VFP2, and VFP3 to the respective field plates 242 (FP1, FP2, and FP3) that are each different from the voltage of the gate electrode 240. Other implementations can include more than one biased field plate position between the gate and the drain, which are individually biased with different field plate bias voltages that are different from the gate voltage. In one example, a biasing circuit provides the respective field plate bias voltages to maintain monotonic voltage increase of the field plate segments in the direction from the source to the drain such that the field plates shape the potential in the drift region 220 to fall approximately uniformly from drain to source, although not a requirement of all possible implementations.

The example semiconductor devices 100 and 200 provide respective field plate voltage bias circuits 190 and 290 that are configured, when the semiconductor devices 100, 200 are powered and operating to provide a non-zero field plate bias voltage VFP to the field plate 142 or field plates 242 that is different from the voltage of the gate electrode 140, 240. In addition, the field plate voltage bias circuit 290 in the multiple field plate example of FIG. 2 in one example provides monotonically increasing voltages to the respective field plates 242 in the direction from the gate electrode 240 to the drain such that the field plates shape the potential in the drift region to fall approximately uniformly in the direction from the drain to the source, although not a requirement of all possible implementations.

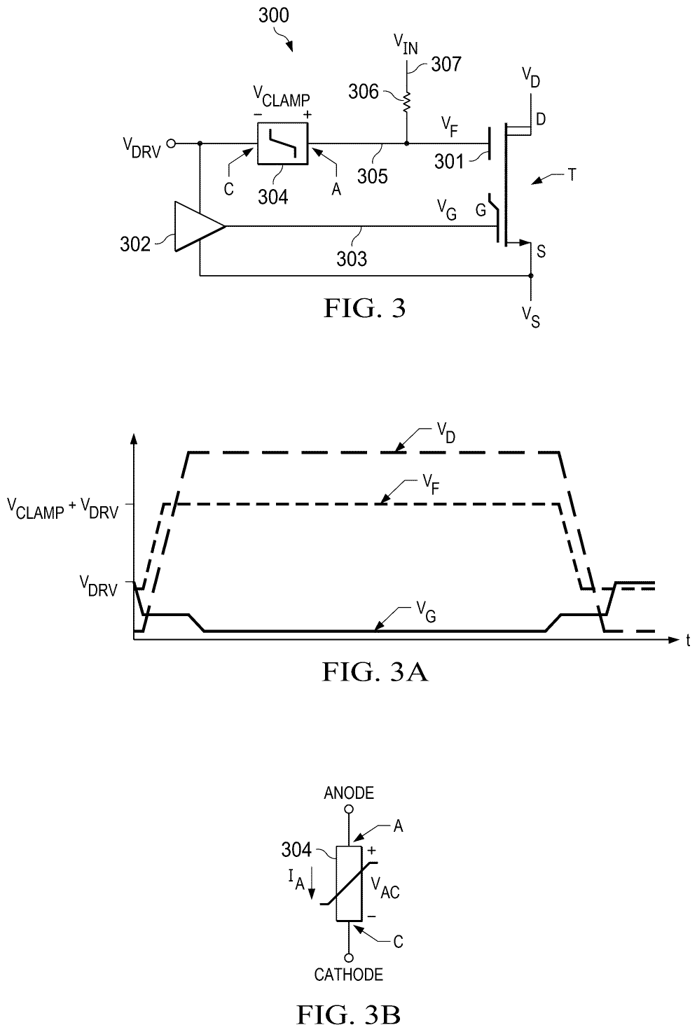

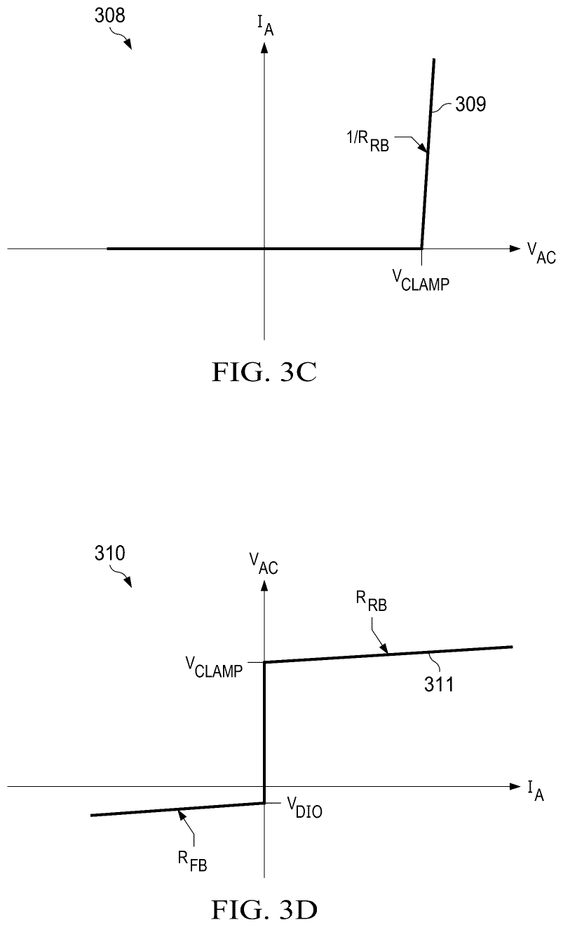

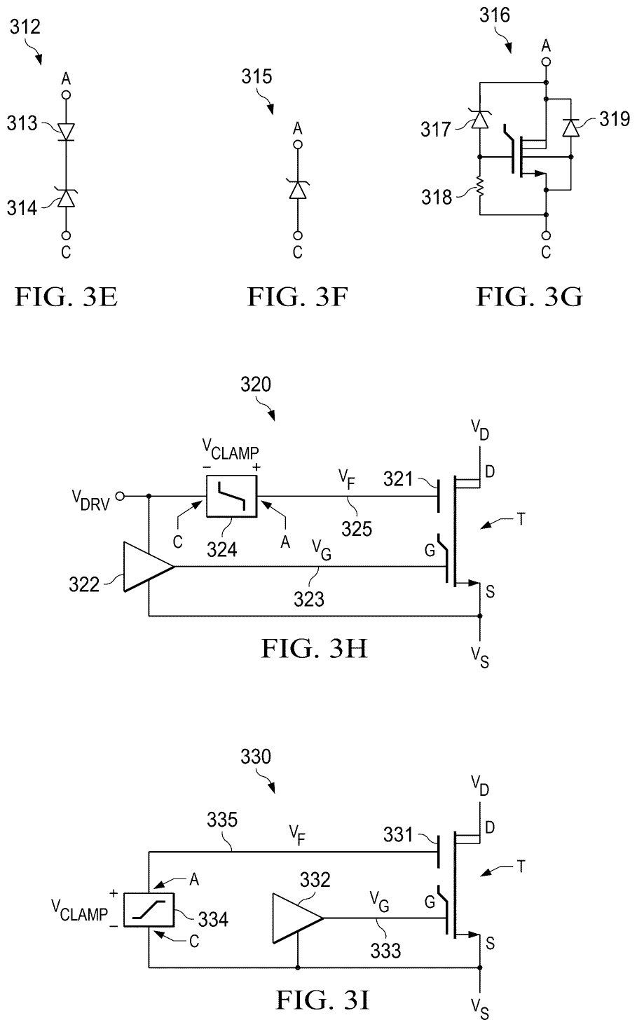

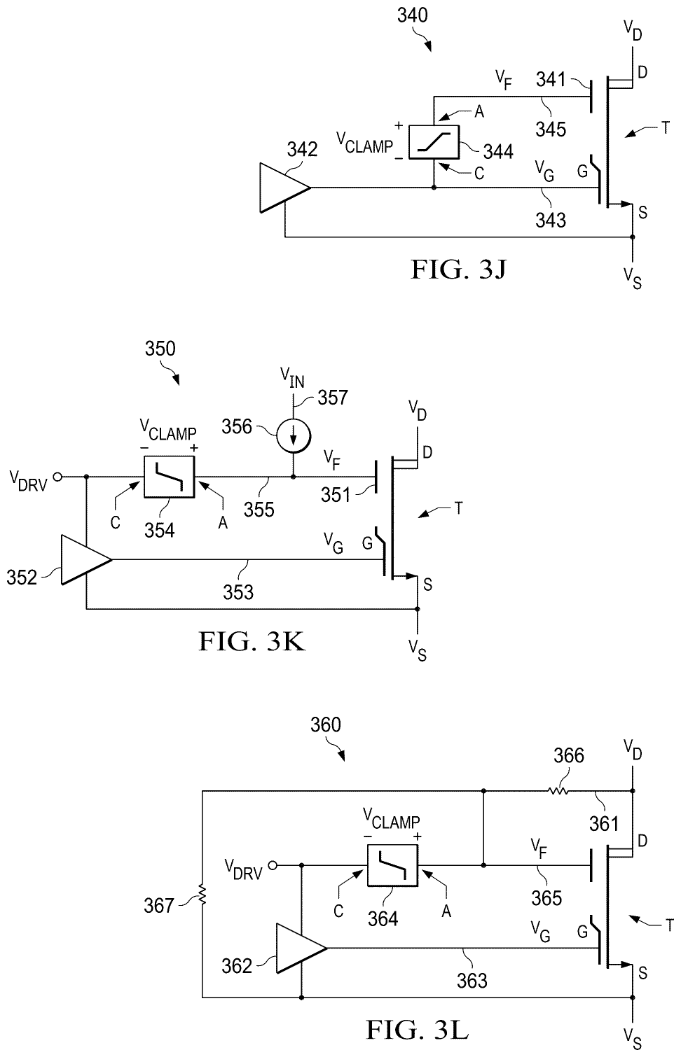

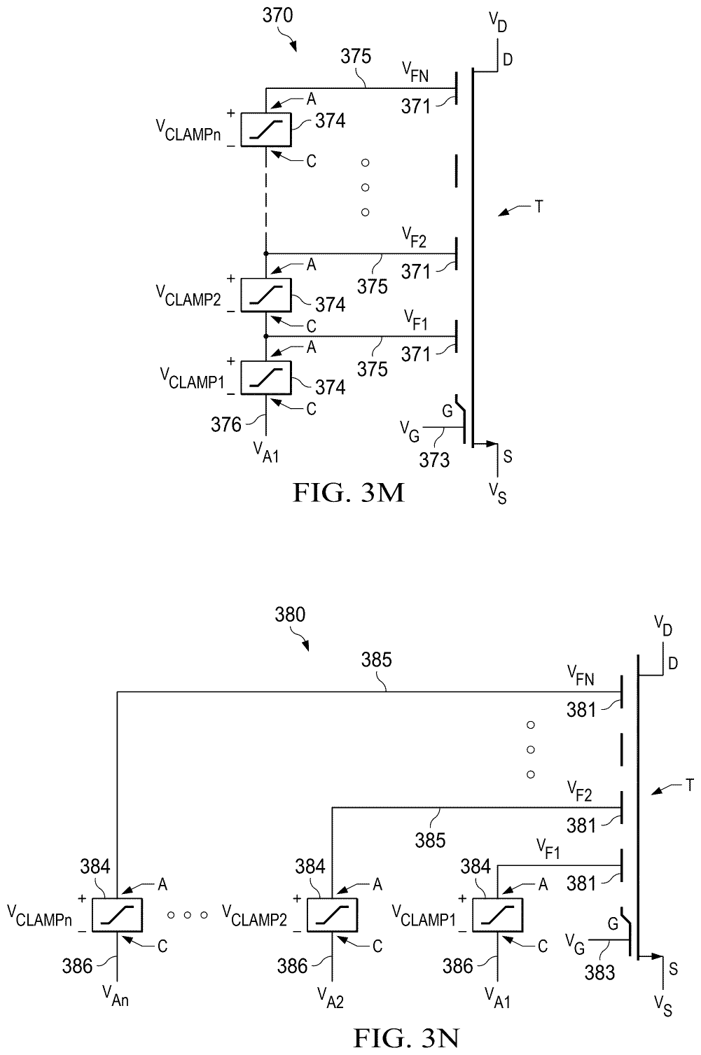

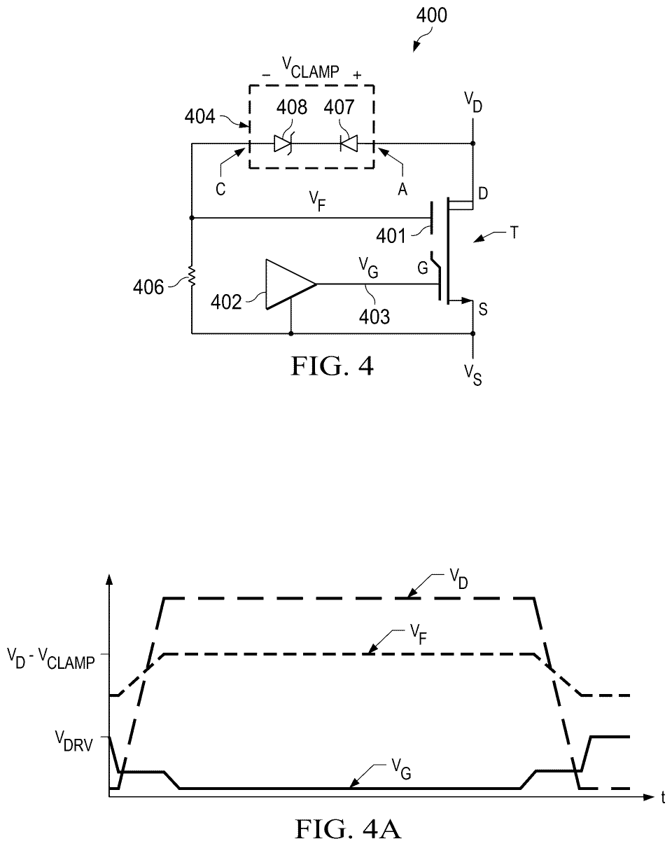

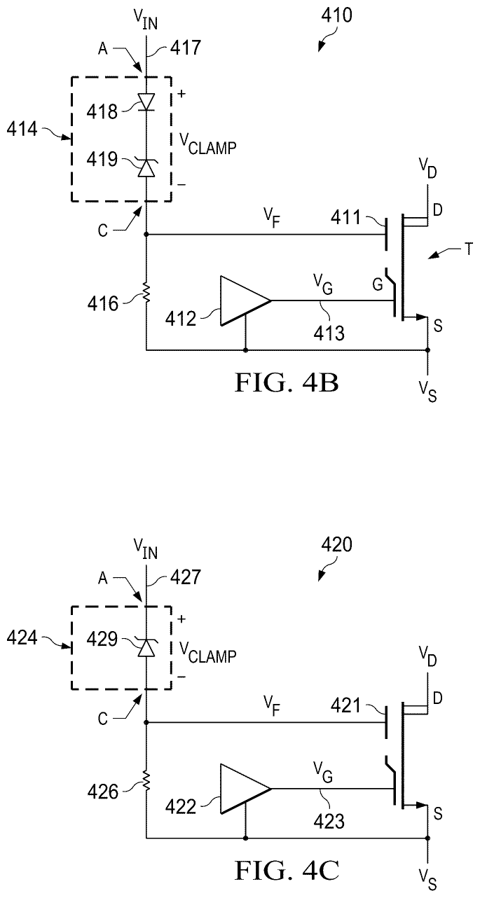

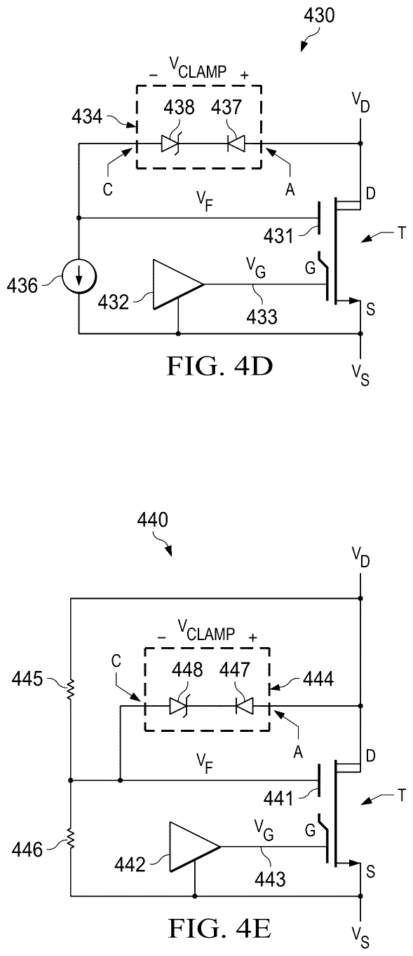

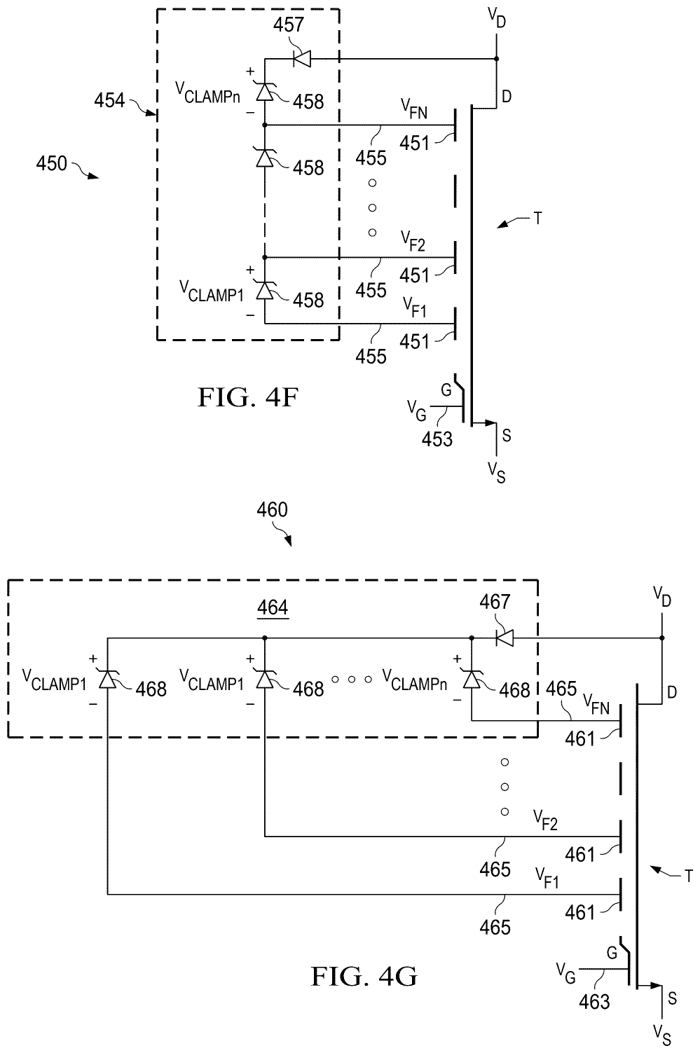

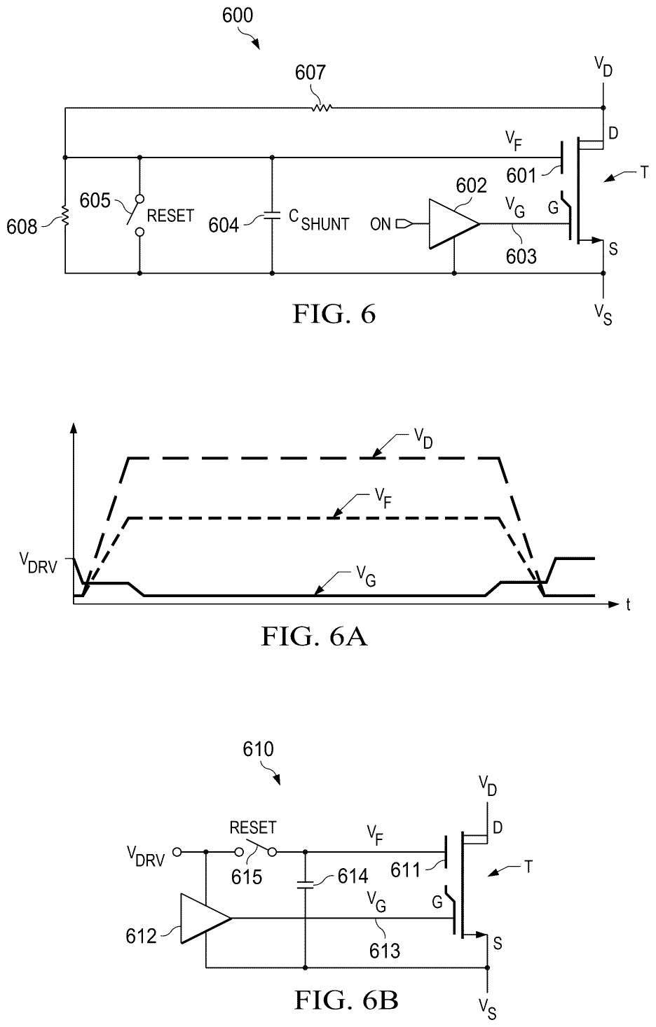

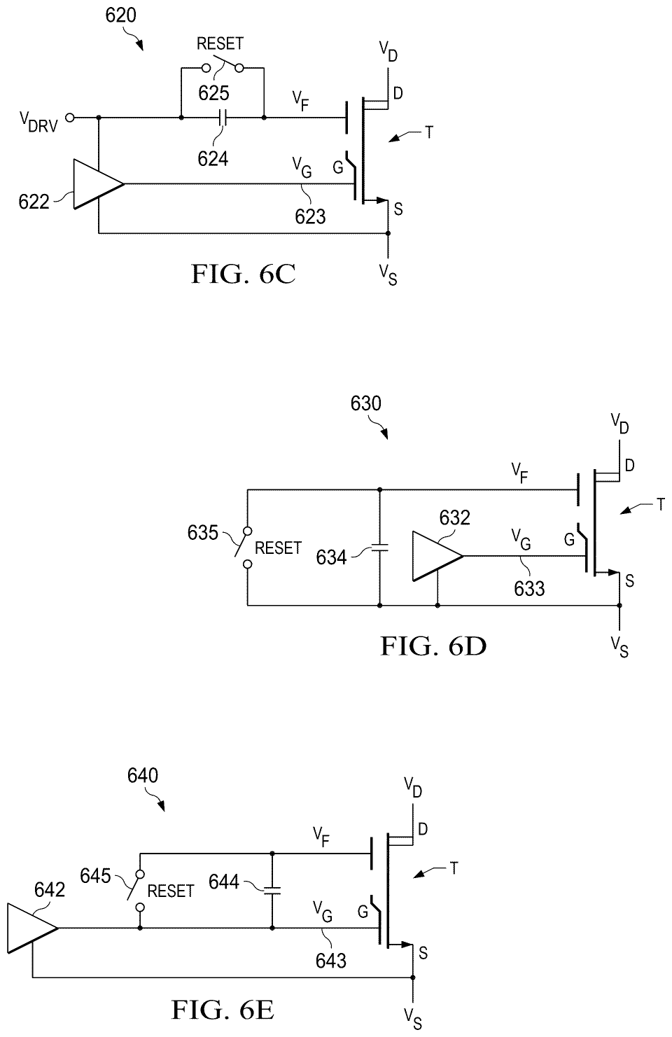

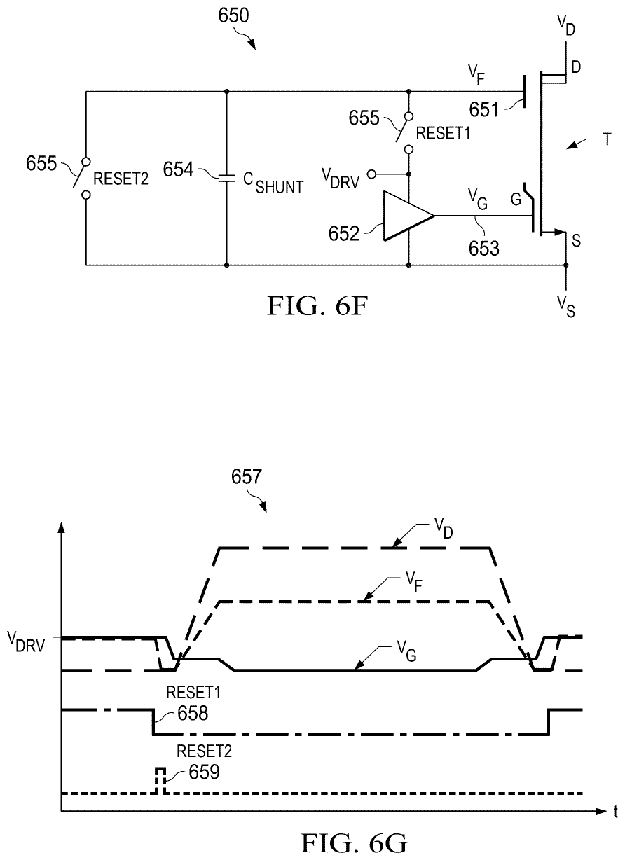

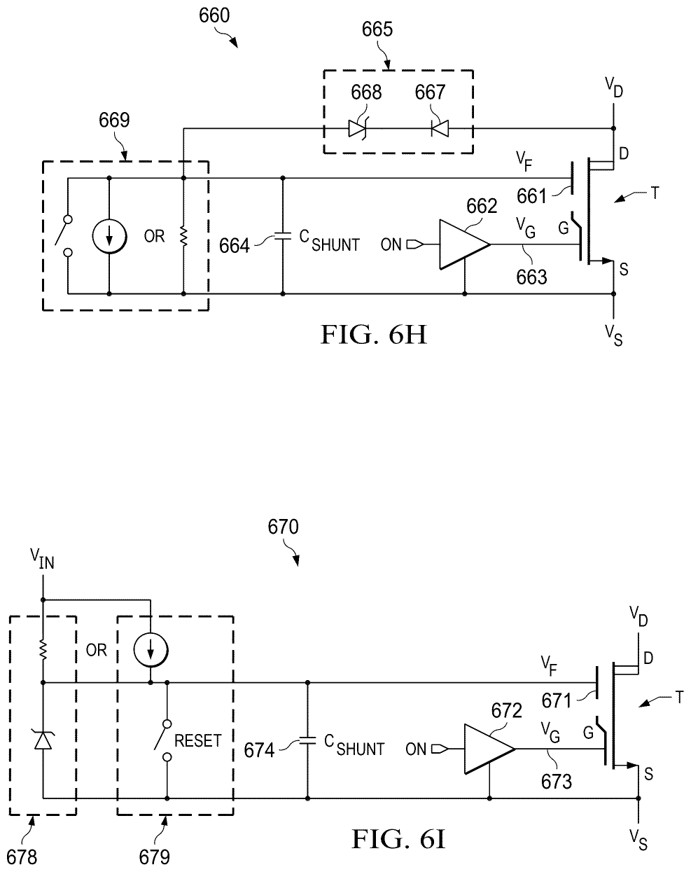

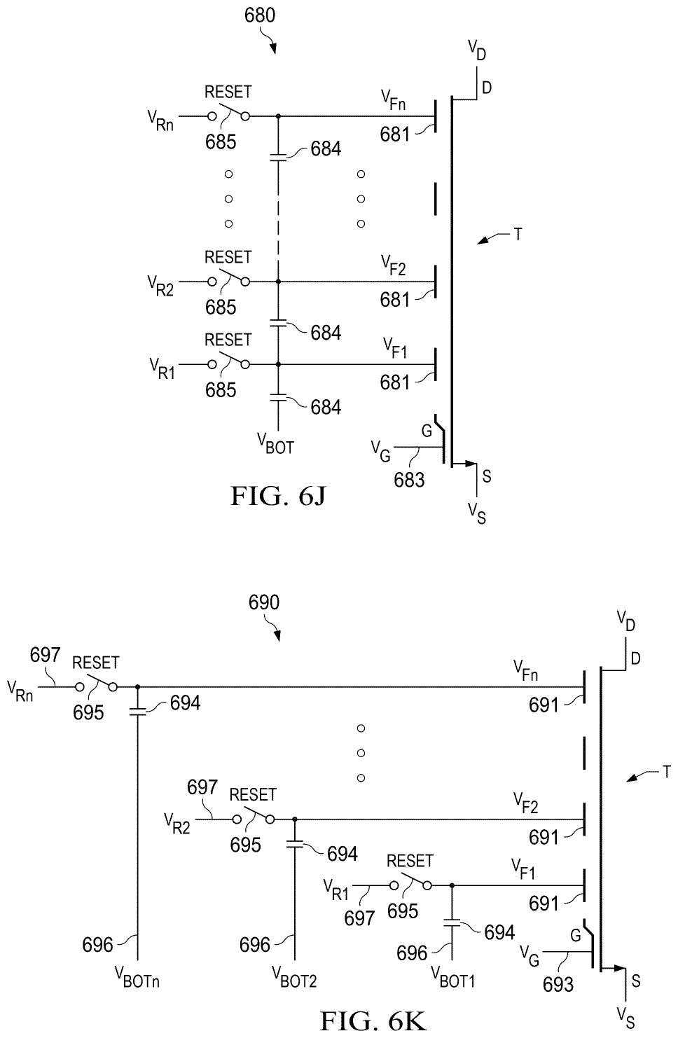

FIGS. 3-16A illustrate examples of suitable bias circuits that can be used in the example semiconductor devices 100 and 200 or other single or multiple biased field plate drain extended transistors. In certain examples (e.g., FIGS. 3, 3H, 3J, 3L, 6E, 6F, 7B, 7D, 9-9B) a bias circuit includes an output coupled to the field plate and a bias input coupled to a gate drive circuit (e.g., gate driver 192 above). In certain examples (e.g., FIGS. 3-3M, 4-4G, 5 and 5A, 6H, 6I, 7D, 7F, 9-9B and 10-15), a diode-based bias circuit includes a clamp circuit with a diode coupled to the field plate. Certain examples (e.g., FIGS. 6-6K, 7-7H, 8, 8A, 11, 12, and 14) illustrate a bias circuit with a reset circuit, some of which may include one or more capacitors, pull up or pull down circuits with a resistor or a current source. In certain implementations (e.g., FIGS. 3, 3G-3N, 9, 9A, 14, 16, 16A) a field plate bias circuit can include one or more additional transistors. In certain examples (e.g., FIGS. 4F, 4G, 6J, 6K, 7G, 7H, 10-12, 15, 16, 16A) a bias circuit can include a resistor coupled to a gate of a clamp circuit transistor.

Some examples employ bias circuitry that shunts the field plate towards the transistor source voltage level, also referred to as a source shunt bias circuit. Other examples use bias circuitry that shunts the field plate towards the transistor drain voltage level (e.g., also referred to as drain shunt bias circuit). Further implementations can provide shunting towards both source and drain voltages. In general, intrinsic capacitances of the drain extended transistor influence the inherent field plate voltage (e.g., VFP) of a given design without voltage biasing. Empirical or simulation-based characterization of a given design can be used, for example, by ramping the drain-source voltage VDS, for example, from zero to a designed breakdown voltage level VB and then back down to zero, and monitoring the voltage of the unbiased field plate to ascertain the field plate voltage at the point where the drain-source voltage is that the breakdown voltage level VB. This measured or simulated value can be compared with a desired target bias voltage for the field plate. The breakdown voltage level VB is a non-monotonic function of the field-plate voltage VFP, for if the VFP is much beyond VB/2, the electric field peaks nearer to the source end of the drift region, and if the VFP is much lower than VB/2 the electric field peaks near the drain end of the drift region. As such, there is a target VFP voltage where the electric field peaks on the source- and drain-side of the drift region can be made approximately equal to facilitate improved (e.g., maximum) VB condition. If the measured or simulated field plate voltage value exceeds the target value, the bias circuit may be designed to shunt toward the source, whereas measured or simulated field plate voltage values below the target value may indicate the need for bias circuitry that shunts toward the drain. Bias circuitry can be used which provides shunting towards both the source and the drain where the measured or simulated field plate voltage is close to the target voltage and/or for large process variations that influence intrinsic capacitances of the field plate.

Referring initially to FIGS. 3-3G, FIG. 3 shows an example active source shunt resistive pull-up bias circuit 300 for a drain extended transistor T with a source S, a gate G, a single field plate 301 (e.g., field plate 142 in FIG. 1 above), and a drain D with a drain voltage V_{D}. A gate driver 302 (e.g., gate driver 192 above) has an output 303 that provides a gate drive voltage signal V_{G} (e.g., the gate voltage) to the gate G and is powered by a gate drive supply with a gate drive supply voltage V_{DRV}. The bias circuit 300 includes a clamp circuit 304 (e.g., a generalized clamp element as also shown in FIG. 3B) with a first terminal A (e.g., an anode of the clamp circuit) and a second terminal C (e.g., a cathode of the clamp circuit 304). The first terminal A is configured to provide a field plate bias voltage signal V_{F} to a circuit node 305 that is coupled to the field plate 301, and a pull-up resistor 306 is coupled between the circuit node 305 and an input node 307 having a circuit input with a voltage V_{IN} (e.g., an input voltage of the semiconductor device 100, such as a DC-DC converter input signal) that is positive with respect to the voltage V_{S} of the source S and with respect to the gate drive supply voltage V_{DRV}. During powered operation, the clamp circuit 304 controls a clamp voltage V_{CLAMP} between the first and second terminals A and C, and the field plate bias voltage signal V_{F} is the clamp voltage plus the gate drive supply voltage (e.g., V_{F}=V_{CLAMP}+V_{DRV}).

FIG. 3A shows a graph with curves representing the drain voltage V_{D}, the field plate bias voltage signal V_{F}, and the gate drive voltage signal V_{G} with respect to the voltage V_{S} of the source S during one excursion of the transistor drain-source voltage (V_{DS}) from zero to a maximal value (e.g., a rated breakdown voltage of the transistor T), and then back to zero during operation of the bias circuit 300 while the gate driver 302 transitions the gate voltage V_{G} low while the drain voltage V_{D} is at the maximal value. The field plate bias voltage signal V_{F} in this example starts at a value slightly below the gate drive supply voltage V_{DRV} and rises during the upward excursion of the drain voltage V_{D} to a steady-state value V_{F}=V_{CLAMP}+V_{DRV}.

FIG. 3B shows the generalized clamp circuit 304 of the bias circuit 300 in FIG. 3 and is used to represent one or more possible clamp circuit implementations in various figures hereinafter. As shown in FIG. 3B, the generalized clamp circuit 304 includes the first terminal A that operates as an anode of the clamp circuit 304 and the second terminal C that operates as a cathode of the clamp circuit 304. A clamp circuit current I_{A} flows into the first terminal A based on a clamp circuit voltage V_{AC} across the first and second terminals A and C (e.g., V_{CLAMP} in the implementation of FIG. 3.

FIG. 3C shows a graph 308 with a curve 309 that illustrates the clamp circuit current I_{A} as a function of the clamp circuit voltage V_{AC} across the first and second terminals A and C of an implementation of the generalized clamp circuit 304 for an implementation of the bias circuit 300 using a dual diode clamp (e.g., FIG. 3E). The clamp circuit 304 in this example conducts no current I_{A} until the clamp circuit voltage V_{AC} across the first and second terminals A and C reaches V_{CLAMP}, and the current I_{A} thereafter rises for further increases of the clamp circuit voltage V_{AC} at a slope 1/R_{RB}.

FIG. 3D shows a graph 310 of the clamp circuit voltage V_{AC} as a function of the clamp circuit current flow I_{A} into the first terminal A. The graph 310 includes a curve 311 for the generalized clamp circuit 304 for an implementation of the bias circuit 300 using an avalanche/Zener diode clamp (e.g., FIGS. 3F and 3G). In this example, the clamp circuit voltage V_{AC} follows a slope R_{RB} for positive clamp circuit current I_{A} and a similar slope R_{RB} for negative current and transitions from a negative voltage V_{DIO} to the clamp voltage V_{CLAMP}, where the negative voltage V_{DIO} is the forward diode drop of the junction diode 313 diode of the clamp circuit 312 of FIGS. 3F and 3G.

FIGS. 3E-3G illustrate respective non-limiting implementations that may be used for the generalized clamp circuit or generalized clamp element 304. FIG. 3E shows one example of a generalized clamp element implementation 312 with junction diode 313 and Zener diode 314. In this example, an anode of the junction diode 313 is connected to the first terminal A, a cathode of the junction diode 313 is connected to a cathode of the Zener diode 314, and the anode of the Zener diode 314 as connected to the second terminal C of the generalized clamp element implementation 312.

FIG. 3F shows an example of the generalized clamp element 315 with a Zener diode. This example has the cathode of the Zener diode connected to the first terminal A and the anode of the Zener diode connected to the second terminal C. The graphs of FIGS. 3A and 3D above are representative of one implementation of the bias circuit 300 of FIG. 3 using a clamp circuit 304 corresponding to the single Zener generalized clamp element 315 of FIG. 3F. In this example, V_{CLAMP} in FIG. 3D represents the clamping voltage of the Zener diode, and the field plate bias voltage V_{F} in the corresponding implementation of the bias circuit 300 in FIG. 3 is approximately V_{DRV}−V_{DIO} when V_{DS} is near 0V and the field plate bias voltage V_{F} is approximately V_{DRV}+V_{ZENER} when V_{DS} nears the breakdown voltage VB, where V_{DRV} is the driver supply voltage, V_{DIO} is the forward diode drop of the Zener diode, and V_{ZENER} is the Zener voltage.

Referring again to the example bias circuit 300 of FIG. 3, alternatives or variants to this circuit configuration can include connecting the clamp element first terminal A instead to the source voltage V_{S}, the gate voltage V_{G}, or to another supply voltage node (not shown, e.g., referred to VS) with corresponding changes to the clamp voltage V_{CLAMP}. In these or other alternate implementations, an active clamp can be implemented in numerous ways as described further below. In these or other examples, a DC biasing resistor, such as the pull up resistor 306 in FIG. 3 or a pulldown resistor may instead be implemented in numerous ways (e.g., current source, resistor divider from V_{D} to V_{S}, etc.).

FIG. 3G shows another example implementation 316 of the generalized clamp element 304 with first and second terminals A and C, respectively. The clamp element 316 of FIG. 3G includes a hybrid circuit with a Zener diode 317, a resistor 318 and an n-channel metal oxide semiconductor (e.g., NMOS) transistor 319. In this example, the cathode of the Zener diode 317 and the drain of the transistor 319 are connected to the first terminal A, the source of the transistor 319 is connected to the second terminal C, the anode of the Zener diode 317 is connected to the gate of the transistor 319, and the resistor 318 is connected between the gate and the source of the transistor 319.

FIGS. 3H-3J show three example alternate cathode connection variations of an active source-based shunt bias circuit for a single biased field plate of a drain extended transistor, illustrated using the generalized clamp element as described above. In various implementations, the generalized clamp element shown in the examples of FIGS. 3H-3J can be any of the examples shown in FIGS. 3E-3G, although different clamp circuits can be used in other implementations.

FIG. 3H shows a source shunt bias circuit 320 for the drain extended transistor T with source S, gate G, a field plate 321 (e.g., field plate 142 in FIG. 1 above), and drain D with the drain voltage V_{D}. A gate driver 322 has an output 323 that provides a gate drive voltage signal V_{G} to the gate G and the gate driver 322 is powered by a gate drive supply with a gate drive supply voltage V_{DRV}. A clamp circuit 324 (e.g., any of the examples shown in FIGS. 3E-3G or other) has a first terminal A coupled to a circuit node 325 that is coupled to the field plate 321, and a second terminal C coupled to the gate drive supply. The first terminal A is configured to provide a field plate bias voltage signal V_{F} to the field plate 321 that is the clamp voltage plus the gate drive supply voltage (e.g., V_{F}=V_{CLAMP}+V_{DRV}). In an implementation using the clamp element of FIG. 3E or 3F, the source shunt bias circuit 320 has the Zener diode anode coupled to the gate drive supply voltage V_{DRV}. In an implementation using the clamp element of FIG. 3G, the source shunt bias circuit 320 has the Zener diode anode coupled to the gate drive supply voltage V_{DRV} through the resistor 318 of FIG. 3G, and the source of the transistor 319 is connected to the gate drive supply voltage V_{DRV} at the second terminal C.

FIG. 3I shows a source shunt bias circuit 330 for the drain extended transistor T with source S, gate G, a field plate 331 (e.g., field plate 142 in FIG. 1 above), and drain D with the drain voltage V_{D}. A gate driver 332 has an output 333 that provides a gate drive voltage signal V_{G} to the gate G. A clamp circuit 334 (e.g., any of the examples shown in FIGS. 3E-3G or other) has a first terminal A coupled to a circuit node 335 that is coupled to the field plate 331, and a second terminal C coupled to the source S. The first terminal A is configured to provide a field plate bias voltage signal V_{F} to the field plate 331 that is the clamp voltage V_{CLAMP} with respect to the source voltage V_{S}. In an implementation using the clamp element of FIG. 3E or 3F, the source shunt bias circuit 330 has the Zener diode anode coupled to the source S V_{DRV}. In an implementation using the clamp element of FIG. 3G, the shunt bias circuit 330 has the Zener diode anode coupled to the transistor source S through the resistor 318 of FIG. 3G, and the source of the transistor 319 is connected to the source S of the transistor T.

FIG. 3J shows a source shunt bias circuit 340 for the drain extended transistor T with source S, gate G, a field plate 341 (e.g., field plate 142 in FIG. 1 above), and drain D with the drain voltage V_{D}. A gate driver 342 has an output 343 that provides a gate drive voltage signal V_{G} to the gate G. A clamp circuit 344 (e.g., any of the examples shown in FIGS. 3E-3G or other) has a first terminal A coupled to a circuit node 345 that is coupled to the field plate 341, and a second terminal C coupled to the gate driver output 343. The first terminal A is configured to provide a field plate bias voltage signal V_{F} to the field plate 341 that is the clamp voltage plus the gate voltage (e.g., V_{F}=V_{CLAMP}+V_{G}). In an implementation using the clamp element of FIG. 3E or 3F, the source shunt bias circuit 340 has the Zener diode anode coupled to the gate driver output 343. In an implementation using the clamp element of FIG. 3G, the source shunt bias circuit 340 has the Zener diode anode coupled to the gate driver output 343 through the resistor 318 of FIG. 3G, and the source of the transistor 319 is connected to the gate driver output 343 at the second terminal C.

FIG. 3K shows an active source shunt bias circuit 350 for the drain extended transistor T with source S, gate G, a field plate 351 (e.g., field plate 142 in FIG. 1 above), and drain D with the drain voltage V_{D} with a shunt current source pull up to the device input voltage V_{IN}. A gate driver 352 has an output 353 that provides a gate drive voltage signal V_{G} to the gate G. A clamp circuit 354 (e.g., any of the examples shown in FIGS. 3E-3G or other) has a first terminal A coupled to a circuit node 355 that is coupled to the field plate 351, and a second terminal C coupled to the gate drive supply. A current source 356 is coupled between the circuit node 355 and an input node 357 having a circuit input with a voltage V_{IN} (e.g., an input voltage of the semiconductor device 100, such as a DC-DC converter input signal). V_{IN} is positive with respect to the voltage V_{S} of the source S and V_{IN} is positive with respect to the gate drive supply voltage V_{DRV}. The first terminal A is configured to provide a field plate bias voltage signal V_{F} to the field plate 351 that is the clamp voltage V_{CLAMP} plus the gate drive supply voltage V_{DRV} (e.g., V_{F}=V_{CLAMP}+V_{DRV}). In an implementation using the clamp element of FIG. 3E or 3F, the source shunt bias circuit 350 has the Zener diode anode coupled to the gate drive supply (e.g., having the gate drive supply voltage V_{DRV}). In an implementation using the clamp element of FIG. 3G, the source shunt bias circuit 350 has the Zener diode anode coupled to the gate drive supply through the resistor 318 of FIG. 3G, and the source of the transistor 319 is connected to the gate drive supply at the second terminal C.

FIG. 3L shows an active source shunt bias circuit 360 for the drain extended transistor T with source S, gate G, a field plate 351 (e.g., field plate 142 in FIG. 1 above), and drain D with the drain voltage V_{D} with a referred resistor divider between the source S and the drain D. A gate driver 362 has an output 363 that provides a gate drive voltage signal V_{G} to the gate G and is powered by a gate drive supply node with a gate drive supply voltage V_{DRV}. A clamp circuit 364 (e.g., any of the examples shown in FIGS. 3E-3G or other) has a first terminal A coupled to a circuit node 365 that is coupled to the field plate 361, and a second terminal C coupled to the gate drive supply. A resistor divider circuit includes a first resistor 366 with a first terminal coupled to the transistor drain D, and a second terminal coupled to the circuit node 365 (e.g., the first terminal A of the clamp circuit 364). The resistor divider circuit also includes a second resistor 367 with a first terminal coupled to the circuit node 365, and a second terminal coupled to the transistor source S.

The first terminal A of the clamp circuit is configured to provide a field plate bias voltage signal V_{F} to the field plate 361 that is the clamp voltage V_{CLAMP} plus the gate drive supply voltage V_{DRV} (e.g., V_{F}=V_{CLAMP}+V_{DRV}). In one example, the values of the respective first and second resistors 366 and 367 are designed to correspond to the field plate bias voltage signal V_{F} being approximately V_{CLAMP} +V_{DRV} when the maximum rated drain-source voltage is approximately equal to a rated breakdown voltage of the transistor T. In an implementation using the clamp element of FIG. 3E or 3F, the source shunt bias circuit 360 has the Zener diode anode coupled to the gate drive supply (e.g., having the gate drive supply voltage V_{DRV}). In an implementation using the clamp element of FIG. 3G, the source shunt bias circuit 360 has the Zener diode anode coupled to the gate drive supply through the resistor 318 of FIG. 3G, and the source of the clamp circuit transistor 319 is connected to the gate drive supply at the second terminal C. In other implementations, the second terminal of the second resistor 367 can be coupled to a circuit node other than the source S of the transistor T and/or the first terminal of the first resistor 366 can be coupled to another circuit node that can be other than the drain D of the transistor T.

FIGS. 3M and 3N show bias circuits 370 and 380 with respective series and parallel clamp circuit implementations for biasing multiple field plates of a drain extended transistor T (e.g., FIG. 2 above). These examples show individual clamp circuits (e.g., 374 in FIGS. 3M and 384 in FIG. 3N), which can be any of the examples shown in FIGS. 3E-3G or other clamp circuits or combinations thereof in various implementations. FIGS. 3M and 3N illustrate respective transistors T having three illustrated field plates, each at different field plate bias voltages, but other implementations can have any suitable integer number “n” field plates and associated bias voltages, where n is greater than 1. In other implementations, a hybrid stacked/parallel clamp structure can be used for generating monotonically increasing field plate bias voltages for two or more field plates of a drain extended transistor.

FIG. 3M shows a bias circuit 370 with a series or stacked arrangement of clamp circuits 374 for active source shunt field plate stacked clamps. The bias circuit 370 includes a series arrangement (e.g., stacked) of clamp circuits 374. The individual clamp circuits 374 can be the examples shown in FIGS. 3E-3G or other clamp circuits or combinations thereof. A first clamp circuit 374 has a first terminal A connected to a first instance of an output node 375 that is coupled to a first field plate 371, as well as a second terminal C coupled to a reference node 376 having a reference voltage V_{A1}, which can be positive with respect to the voltage V_{S} of the source S or can be the source voltage. For example, the reference node 376 can be connected to the source S, a gate driver supply node (e.g., at a gate driver supply voltage V_{DRV} as discussed above), a gate driver output node 373 that provides a gate drive voltage signal V_{G} to the gate G, or other suitable reference node of the semiconductor device. The first clamp circuit 374 provides a controlled voltage at the first output node instance 375 to control a first field plate bias voltage signal V_{F1} at the first field plate 371, which is clamped at the reference voltage V_{A1} plus a first clamp voltage V_{CLAMP1} (e.g., V_{F1}=V_{CLAMP1}+V_{A1}).

The second clamp circuit 374 in this example has a first terminal A connected to a corresponding second instance of an output node 375 that is coupled to a second field plate 371 with a second field plate bias voltage signal V_{F2}. A second terminal C of the second clamp circuit 374 is coupled to the first terminal A of the first clamp circuit 374 that has the first field plate bias voltage signal V_{F1}. The second clamp circuit 374 provides a controlled voltage at the second output node instance 375 to control a second field plate bias voltage signal V_{F2} at the second field plate 371, which is clamped at the first field plate bias voltage signal V_{F1} plus a second clamp voltage V_{CLAMP2} (e.g., V_{F2}=V_{F1}+V_{CLAMP2}).

Any included further clamp circuits 374 are similarly connected with an “n^{th}” or final clamp circuit 374 that provides a controlled voltage at the corresponding output node instance 375 to control a corresponding field plate bias voltage signal V_{Fn} at the corresponding final field plate 371. The final field plate 371 is clamped at the voltage of the previous field plate bias voltage signal V_{Fn-1} plus a corresponding n^{th} clamp voltage V_{CLAMPn} (e.g., V_{Fn}=V_{Fn-1}+V_{CLAMPn}). In other implementations, the stacked or series-connected bias circuit 370 can further include pull-ups circuitry (e.g., a resistor or a current source), pulldown circuitry (e.g., a resistor or a current source), one or more resistive voltage divider circuits referenced to suitable nodes (e.g., drain D and source S), or combinations thereof (not shown).

FIG. 3N shows a bias circuit 380 with a parallel clamp circuit implementation for biasing multiple field plates of a drain extended transistor T (e.g., FIG. 2 above). This example includes n instances of a clamp circuit 384 for active source shunt field plate clamped biasing. The individual clamp circuits 384 can be the examples shown in FIGS. 3E-3G or other clamp circuits or combinations thereof. A first clamp circuit 384 in FIG. 3N has a first terminal A connected to a first instance of an output node 385 that is coupled to a first field plate 381. The first clamp circuit 384 also has a second terminal C coupled to a first reference node 386 having a first reference voltage V_{A1}, which can be positive with respect to the voltage V_{S} of the source S or can be the source voltage. For example, the reference node 386 can be connected to the source S, a gate driver supply node (e.g., at a gate driver supply voltage V_{DRV} as discussed above), a gate driver output node 383 that provides a gate drive voltage signal V_{G} to the gate G, or other suitable reference node of the semiconductor device. The first clamp circuit 384 provides a controlled voltage at the first output node instance 385 to control a first field plate bias voltage signal V_{F1} at the first field plate 381, which is clamped at the reference voltage V_{A1} plus a first clamp voltage V_{CLAMP1} (e.g., V_{F1}=V_{CLAMP1}+V_{A1}).

The second clamp circuit 384 in FIG. 3N has a first terminal A connected to a corresponding second instance of an output node 385 that is coupled to a second field plate 381 with a second field plate bias voltage signal V_{F2}. A second terminal C of the second clamp circuit 384 is coupled to a second reference node 386 having a second reference voltage V_{A2} that can be positive with respect to the voltage V_{S} of the source S or can be the source voltage. For example, the reference node 386 can be connected to the source S, a gate driver supply node (e.g., at a gate driver supply voltage V_{DRV} as discussed above), a gate driver output node 383 that provides a gate drive voltage signal V_{G} to the gate G, or other suitable reference node of the semiconductor device. The second clamp circuit 384 provides a controlled voltage at the second output node instance 385 to control the second field plate bias voltage signal V_{F2} at the second field plate 381, which is clamped at the second reference voltage V_{A2} plus a second clamp voltage V_{CLAMP2} (e.g., V_{F2}=V_{A2}+V_{CLAMP2}, where V_{F2}>V_{F1}). Any included further clamp circuit(s) 384 is/are similarly connected with an “n^{th}” or final clamp circuit 384 that provides a controlled voltage at the corresponding output node instance 385 to control a corresponding field plate bias voltage signal V_{Fn} at the corresponding final field plate 381. The final field plate 381 is clamped at the voltage of the n^{th} reference voltage V_{An} plus a corresponding n^{th} clamp voltage V_{CLAMPn} (e.g., V_{Fn}=V_{An}+V_{CLAMPn}). In other implementations, the parallel bias circuit 380 can further include pull-ups circuitry (e.g., a resistor or a current source), pulldown circuitry (e.g., a resistor or a current source), one or more resistive voltage divider circuits referenced to suitable nodes (e.g., drain D and source S), or combinations thereof (not shown).

Certain of the above bias circuit examples of FIGS. 3-3M have an output coupled to the field plate and a bias input coupled to a gate drive circuit (e.g., FIGS. 3, 3H, 3J, 3L), and some have an output coupled to the field plate and a bias input coupled to a gate drive circuit (e.g., gate driver 192 above). In certain example implementations, a diode-based bias circuit includes a clamp circuit with a diode coupled to the field plate. Certain examples (e.g., FIGS. 3, 3G-3N) can have a field plate bias circuit with one or more additional transistors.

Referring to FIGS. 4-4G, further example bias circuits have drain-shunt features and arrangements. The examples in these figures are shown with a dual diode clamping circuit implementation (e.g., FIG. 3D above). In other implementations, individual clamp circuits in FIGS. 4-4G can be the examples shown in FIGS. 3E-3G or other clamp circuits or combinations thereof.

FIG. 4 shows an example active drain shunt resistive pull-down bias circuit 400 for a drain extended transistor T with a source S, a gate G, a single field plate 401 (e.g., field plate 142 in FIG. 1 above), and a drain D with a drain voltage V_{D}. The bias circuit 400 has a clamp circuit 404 with a clamp voltage V_{CLAMP} and includes a first terminal A connected to the drain D and a second terminal C. The clamp circuit 404 includes a junction diode 407 with an anode coupled to the first terminal A of the clamp circuit 404. A pulldown resistor 406 is coupled between the field plate 401 and the source S of the transistor T. The pulldown resistor 406 may be implemented in numerous ways (e.g., current source, resistor divider from V_{D} to V_{S}, etc.). A cathode of the junction diode 407 is connected to a cathode of a Zener diode 408 of the clamp circuit 404, and the anode of the Zener diode 408 is connected to the second terminal C. In other implementations the clamp circuit 404 can be any of the examples shown in FIGS. 3E-3G above or other clamp circuit or combinations thereof. A gate driver 402 has an output 403 that provides a gate drive voltage signal V_{G} (e.g., the gate voltage) to the gate G. The second terminal C of the clamp circuit 404 is configured to provide a field plate bias voltage signal V_{F} to a circuit node that is coupled to the field plate 401. During powered operation, the clamp circuit 404 controls a clamp voltage V_{CLAMP} between the first and second terminals A and C, and the field plate bias voltage signal V_{F} is the drain voltage minus the clamp (e.g., V_{F}=V_{D}−V_{CLAMP}).

FIG. 4A shows a graph with curves representing the drain voltage V_{D}, the field plate bias voltage signal V_{F}, and the gate drive voltage signal V_{G} of the transistor T in FIG. 4 with respect to the voltage V_{S} of the source S. The graph shows one excursion of the transistor drain-source voltage (V_{DS}) from zero to a maximal value (e.g., a rated breakdown voltage of the transistor T), and then back to zero during operation of the bias circuit 400 while the gate driver 402 transitions the gate voltage V_{G} low while the drain voltage V_{D} is at the maximal value. The field plate bias voltage signal V_{F} in this example starts at a value slightly below V_{D}−V_{CLAMP} and rises during the upward excursion of the drain voltage V_{D} to a steady-state value V_{F}=V_{D}−V_{CLAMP}.

FIG. 4B shows another example active drain shunt resistive pull-down bias circuit 410 for a drain extended transistor T with a source S, a gate G, a single field plate 411 (e.g., field plate 142 in FIG. 1 above), and a drain D with a drain voltage V_{D}. The bias circuit 410 has a clamp circuit 414 with a clamp voltage V_{CLAMP} and includes a first terminal A connected to the drain D and a second terminal C. The clamp circuit 414 includes a junction diode 418 with an anode coupled to the first terminal A of the clamp circuit 414 and to an input 417 of the semiconductor device having an input voltage V_{IN}. A pulldown resistor 416 is coupled between the field plate 411 and the source S of the transistor T. The pulldown resistor 416 may be implemented in numerous ways (e.g., current source, resistor divider from V_{D} to V_{S}, etc.). A cathode of the junction diode 418 is connected to a cathode of a Zener diode 419 of the clamp circuit 414, and the anode of the Zener diode 419 is connected to the second terminal C. In other implementations the clamp circuit 414 can be any of the examples shown in FIGS. 3E-3G above or other clamp circuit or combinations thereof. A gate driver 412 has an output 413 that provides a gate drive voltage signal V_{G} (e.g., the gate voltage) to the gate G. The second terminal C of the clamp circuit 414 is configured to provide a field plate bias voltage signal V_{F} to a circuit node that is coupled to the field plate 411. During powered operation, the clamp circuit 414 controls a clamp voltage V_{CLAMP} between the first and second terminals A and C, and the field plate bias voltage signal V_{F} is the input voltage minus the clamp voltage (e.g., V_{F}=V_{IN}−V_{CLAMP}).

FIG. 4C shows another example active drain shunt resistive pull-down bias circuit 420 for a drain extended transistor T with a source S, a gate G, a single field plate 421 (e.g., field plate 142 in FIG. 1 above), and a drain D with a drain voltage V_{D}. The bias circuit 420 has a clamp circuit 424 with a clamp voltage V_{CLAMP} and includes a first terminal A connected to an input 427 and a second terminal C. The clamp circuit 424 includes a Zener diode 429 with a cathode coupled to the first terminal A of the clamp circuit 424 and to an input 427 of the semiconductor device having an input voltage V_{IN}. A pulldown resistor 426 is coupled between the field plate 421 and the source S of the transistor T. The pulldown resistor 426 may be implemented in numerous ways (e.g., current source, resistor divider from V_{D} to V_{S}, etc.). An anode of the Zener diode 429 is connected to the second terminal C of the clamp circuit 424. In other implementations the clamp circuit 424 can be any of the examples shown in FIGS. 3E-3G above or other clamp circuit or combinations thereof. A gate driver 422 has an output 423 that provides a gate drive voltage signal V_{G} (e.g., the gate voltage) to the gate G. The second terminal C of the clamp circuit 424 is configured to provide a field plate bias voltage signal V_{F} to a circuit node that is coupled to the field plate 421. During powered operation, the clamp circuit 424 controls a clamp voltage V_{CLAMP} between the first and second terminals A and C, and the field plate bias voltage signal V_{F} is the input voltage minus the clamp voltage (e.g., V_{F}=V_{IN}−V_{CLAMP}).

FIG. 4D shows an example active drain shunt current source pull-down bias circuit 430 for a drain extended transistor T with a source S, a gate G, a single field plate 431 (e.g., field plate 142 in FIG. 1 above), and a drain D with a drain voltage V_{D}. The bias circuit 430 has a clamp circuit 434 with a clamp voltage V_{CLAMP} and includes a first terminal A connected to the drain D and a second terminal C. The clamp circuit 434 includes a junction diode 437 with an anode coupled to the first terminal A of the clamp circuit 434. A current source 436 is coupled between the field plate 431 and the source S of the transistor T. The current source 436 may be implemented in numerous ways (e.g., resistor is shown in FIG. 4, resistor divider from V_{D} to V_{S}, etc.). A cathode of the junction diode 437 is connected to a cathode of a Zener diode 438 of the clamp circuit 434, and the anode of the Zener diode 438 is connected to the second terminal C. In other implementations the clamp circuit 434 can be any of the examples shown in FIGS. 3E-3G above or other clamp circuit or combinations thereof. A gate driver 432 has an output 433 that provides a gate drive voltage signal V_{G} (e.g., the gate voltage) to the gate G. The second terminal C of the clamp circuit 434 is configured to provide a field plate bias voltage signal V_{F} to a circuit node that is coupled to the field plate 431. During powered operation, the clamp circuit 434 controls a clamp voltage V_{CLAMP} between the first and second terminals A and C, and the field plate bias voltage signal V_{F} is the drain voltage minus the clamp (e.g., V_{F}=V_{D}−V_{CLAMP}).

FIG. 4E shows an example active shunt drain-source voltage (V_{DS}) referred resistor divider bias circuit 440 for a drain extended transistor T with a source S, a gate G, a single field plate 441 (e.g., field plate 142 in FIG. 1 above), and a drain D with a drain voltage V_{D}. The bias circuit 440 has a clamp circuit 444 with a clamp voltage V_{CLAMP} and includes a first terminal A connected to the drain D and a second terminal C. The clamp circuit 444 includes a junction diode 447 with an anode coupled to the first terminal A of the clamp circuit 444. A cathode of the junction diode 447 is connected to a cathode of a Zener diode 448 of the clamp circuit 444, and the anode of the Zener diode 448 is connected to the second terminal C. In other implementations the clamp circuit 444 can be any of the examples shown in FIGS. 3E-3G above or other clamp circuit or combinations thereof. A resistor divider includes a first resistor 445 and a second resistor 446. The first resistor 445 has a first terminal coupled to the drain D and a second terminal coupled to the field plate 441 of the transistor T. The second resistor 446 has a first terminal coupled to the field plate 441, and a second terminal coupled to the source S of the transistor T. A gate driver 442 has an output 443 that provides a gate drive voltage signal V_{G} (e.g., the gate voltage) to the gate G. The second terminal C of the clamp circuit 444 is configured to provide a field plate bias voltage signal V_{F} to a circuit node that is coupled to the field plate 441. During powered operation, the clamp circuit 444 controls a clamp voltage V_{CLAMP} between the first and second terminals A and C, and the field plate bias voltage signal V_{F} is the drain voltage minus the clamp (e.g., V_{F}=V_{D}−V_{CLAMP}).

FIGS. 4F and 4G show bias circuits 450 and 460 with respective series (e.g., stacked) and parallel clamp circuit implementations for biasing multiple field plates of a drain extended transistor T (e.g., FIG. 2 above). These examples show individual clamp circuits (e.g., 458 in FIGS. 4F and 468 in FIG. 4G), which can be any of the examples shown in FIGS. 3E-3G or other clamp circuits or combinations thereof in various implementations. FIGS. 4F and 4G illustrate respective transistors T having three illustrated field plates, each at different field plate bias voltages, but other implementations can have any suitable integer number “n” field plates and associated bias voltages, where n is greater than 1. In other implementations, a hybrid stacked/parallel clamp structure can be used for generating monotonically increasing field plate bias voltages for two or more field plates of a drain extended transistor.

FIG. 4F shows a bias circuit 450 with a series or stacked arrangement of clamp circuits 454 for active drain shunt field plate stacked clamping for a drain extended transistor T with a source S, a gate G (e.g., also labeled 453), field plates 451, and a drain D with a drain voltage V_{D}. The bias circuit 450 includes a clamp circuit 454. The individual clamp circuits 454 have a junction diode 457 and stacked or series-connected Zener diodes 458. The stacked clamp circuit 454 has a first terminal coupled to the anode of the junction diode 457 and connected to the drain D of the transistor T. The clamp circuit 454 has an integer number “n” second terminals coupled to respective instances of a circuit node 455 that is connected to a corresponding field plate 451. A first (e.g., top) Zener diode 458 has a cathode coupled to the cathode of the junction diode 457, and an anode coupled to the top field plate 451. The remaining series connected Zener diodes 458 have an anode connected to a respective field plate 451 and a cathode coupled to the Zener diode above. The Zener diodes each have a corresponding clamp voltage (e.g., V_{CLAMP1}, . . . , V_{CLAMPn}), and the success of field plates 451 are biased at a corresponding field plate bias voltage V_{F1}, . . . , V_{Fn}. The uppermost field plate 455 (e.g., nearest the drain D) has a field plate bias voltage V_{Fn} that is the drain voltage V_{D} minus the voltage drop across the junction diode 457 and the uppermost Zener voltage V_{CLAMPn}, and each individual field plate 451 is biased at a respective field plate bias voltage that is lower than the clamp voltage of the next higher field plate 451 by the corresponding Zener diode clamp voltage.

FIG. 4G shows a bias circuit 460 with a parallel clamp circuit implementation for biasing multiple field plates 461 of a drain extended transistor T (e.g., FIG. 2 above) with a source S, a gate G (e.g., also labeled 463), field plates 461, and a drain D with a drain voltage V_{D}. The bias circuit 460 includes a clamp circuit 464 with a junction diode 467 and Zener diodes 468 individually coupled between the junction diode 467 and a respective one of the field plates 461. The clamp circuit 464 has a first terminal coupled to the anode of the junction diode 467 and connected the drain D of the transistor T. The clamp circuit 464 has an integer number “n” second terminals 465 coupled to a corresponding field plate 461 and to the anode of a corresponding one of the Zener diodes 468. The Zener diodes 468 each have a cathode coupled to the cathode of the junction diode 467. In one implementation, the Zener diodes 468 each have different monotonically increasing Zener voltages and associated clamp voltages (e.g., V_{CLAMP1}, . . . , V_{CLAMPn}), with monotonically decreasing Zener voltages and clamp voltages (e.g., V_{CLAMP1}>V_{CLAMP2}>. . . , V_{CLAMPn}) such that the bias voltages of the field plates 461 have monotonically increasing voltage values in the direction from the source S to the drain D (e.g., V_{F1}<V_{F2}<. . . , V_{Fn}).

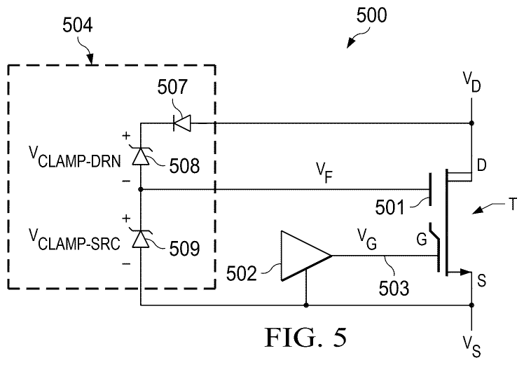

FIG. 5 shows an example hybrid source and drain shunt current source pull-down bias circuit 500 for a drain extended transistor T with a source S, a gate G, a single field plate 501 (e.g., field plate 142 in FIG. 1 above), and a drain D with a drain voltage V_{D}. The bias circuit 500 has a clamp circuit 504 with a first clamp voltage V_{CLAMP-DRN} and a second clamp voltage V_{CLAMP-SRC}. The clamp circuit 504 includes a junction diode 507 with an anode coupled to the drain D, a first Zener diode 508 coupled between the junction diode 507 and the field plate 501 of the transistor T, and a second Zener diode 509 coupled between the field plate 501 and the source S. A cathode of the junction diode 507 is connected to a cathode of a first Zener diode 508 of the clamp circuit 504. The anode of the first Zener diode 508 is connected to the field plate 501. A cathode of the second Zener diode 509 is connected to the field plate 501, and an anode of the second Zener diode 509 is connected to the source S. A gate driver 502 has an output 503 that provides a gate drive voltage signal V_{G} (e.g., the gate voltage) to the gate G. The clamp circuit 504 is configured to provide a field plate bias voltage signal V_{F} to the field plate 501.

Referring also to FIGS. 6-6K, further examples provide capacitive shunt bias circuits to bias one or more field plates of a drain extended transistor T with a source S, a gate G, one or more field plates (e.g., field plate 142 in FIG. 1 above), and a drain D with a drain voltage V_{D}. In one or more examples, the bias circuit is coupled to the field plate or field plates and includes a reset circuit operated by suitable control circuitry (not shown) for coordinated timing with respect to actuation of the transistor gate G. In these or other examples, the bias circuit includes one or more capacitors. In these or other examples, the bias circuit can include a pull up circuit with a resistor or a current source coupled to the drain D. In these or other examples, the bias circuit can include a pulldown circuit with a resistor or current source coupled to a source S of the drain extended transistor T or a resistor divider circuit.

FIG. 6 shows an example active source shunt bias circuit 600 for a drain extended transistor T with a source S, a gate G, a single field plate 601 (e.g., field plate 142 in FIG. 1 above), and a drain D with a drain voltage V_{D}. A gate driver 602 (e.g., gate driver 192 above) has an output 603 that provides a gate drive voltage signal V_{G} (e.g., the gate voltage) to the gate G. The bias circuit 600 includes a clamp circuit configured to provide a field plate bias voltage signal V_{F} to the field plate 601. The clamp circuit in this example includes a capacitor 604 coupled between the field plate 601 and the source S of the transistor T, as well as a reset circuit 605 (e.g., a switch) connected in parallel with the capacitor 604. The bias circuit 600 also includes a resistor divider with a first resistor 607 having a first terminal coupled to the drain D and a second terminal coupled to the field plate 601, as well as a second resistor 608 with a first terminal coupled to the field plate 601 and a second terminal coupled to the source S of the transistor T in parallel with the reset circuit 605 and the capacitor 604. In one example, the reset circuit 605 is controlled in a synchronized fashion with respect to the gate driver 602, for example, to close (e.g., connect the field plate 601 to the source S) at a fixed temporal relationship with respect to a gate driver signal that turns the transistor T on, and then opens the reset circuit 605 to allow the capacitor 604 to charge at a fixed temporal relationship to a gate drive signal that turns the transistor T off.

FIG. 6A shows a graph with curves representing the drain voltage V_{D}, the field plate bias voltage signal V_{F}, and the gate drive voltage signal V_{G} with respect to the voltage V_{S} of the source S during one excursion of the transistor drain-source voltage (V_{DS}) from zero to a maximal value (e.g., a rated breakdown voltage of the transistor T), and then back to zero during operation of the bias circuit 600 while the gate driver 602 transitions the gate voltage V_{G} low while the drain voltage V_{D} is at the maximal value. The field plate bias voltage signal V_{F} in this example starts at approximately zero and rises during the upward excursion of the drain voltage V_{D} to a steady-state value V_{F}. In one example, the reset circuit 605 initializes the field plate bias voltage signal V_{F} to 0 V when V_{D} is near 0 V (e.g., by monitoring V_{DS} or V_{G}). The capacitance C_{SHUNT} of the capacitor 604 can be chosen such that transition of V_{DS} from 0 V to a rated breakdown voltage V_{BV} translates the field plate 601 from 0V to a target field plate bias voltage V_{F}, and the capacitor 604 can be created using metal system of the semiconductor device or any suitable technique. In other implementations, the field plate 601 can alternatively be reset to another voltage, such as V_{S}, V_{G}, or another supply (e.g., referred to V_{S}) with any suitable corresponding change to the capacitance C_{SHUNT}. In these or other implementations, the reset circuit 605 can be omitted, for example, if the resistor divider (e.g., resistors 607 and 608) is well matched such that when V_{DS}=a rated breakdown voltage V_{BV}, V_{FS}=V_{FS(TARGET)}. Alternative topologies are possible, for example, hybrid active and capacitive with reset circuit closed after the gate G is turned on and the reset circuit 605 opened before the gate G turns off.

FIG. 6B shows an example active source shunt bias circuit 610 for a drain extended transistor T with a source S, a gate G, a single field plate 611 (e.g., field plate 142 in FIG. 1 above), and a drain D with a drain voltage V_{D}. A gate driver 612 (e.g., gate driver 192 above) has an output 613 that provides a gate drive voltage signal V_{G} (e.g., the gate voltage) to the gate G and is powered by a gate drive supply with a gate drive supply voltage V_{DRV}. The bias circuit 610 includes a clamp circuit configured to provide a field plate bias voltage signal V_{F} to the field plate 611. The clamp circuit in this example includes a capacitor 614 coupled between the field plate 611 and the source S of the transistor T, as well as a reset circuit 615 (e.g., a switch) connected between the capacitor 614 and the gate drive supply to reset the field plate 611 to a gate drive voltage V_{DRV}, where the reset circuit is configured to close after the gate G is turned on and the reset circuit 615 is configured to open before the gate G turns off.

FIG. 6C shows an example active source shunt bias circuit 620 for a drain extended transistor T with a source S, a gate G, a single field plate 621 (e.g., field plate 142 in FIG. 1 above), and a drain D with a drain voltage V_{D}. A gate driver 622 (e.g., gate driver 192 above) has an output 623 that provides a gate drive voltage signal V_{G} (e.g., the gate voltage) to the gate G and is powered by a gate drive supply with a gate drive supply voltage V_{DRV}. The bias circuit 620 includes a clamp circuit configured to provide a field plate bias voltage signal V_{F} to the field plate 621. The clamp circuit in this example includes a capacitor 624 coupled between the field plate 621 and the gate drive supply, as well as a reset circuit 625 (e.g., a switch) connected in parallel with the capacitor 624 to reset the field plate 621 to a gate drive voltage V_{DRV}, where the reset circuit is configured to close after the gate G is turned on and the reset circuit 625 is configured to open before the gate G turns off.

FIG. 6D shows an example active source shunt bias circuit 630 for a drain extended transistor T with a source S, a gate G, a single field plate 631 (e.g., field plate 142 in FIG. 1 above), and a drain D with a drain voltage V_{D}. A gate driver 632 (e.g., gate driver 192 above) has an output 633 that provides a gate drive voltage signal V_{G} (e.g., the gate voltage) to the gate G and is powered by a gate drive supply with a gate drive supply voltage V_{DRV}. The bias circuit 630 includes a clamp circuit configured to provide a field plate bias voltage signal V_{F} to the field plate 631. The clamp circuit in this example includes a capacitor 634 coupled between the field plate 631 and the source S of the transistor T, as well as a reset circuit 635 (e.g., a switch) connected in parallel with the capacitor 634 to reset the field plate 631 to the source voltage V_{S}, where the reset circuit is configured to close after the gate G is turned on and the reset circuit 635 is configured to open before the gate G turns off.

FIG. 6E shows an example active source shunt bias circuit 640 for a drain extended transistor T with a source S, a gate G, a single field plate 641 (e.g., field plate 142 in FIG. 1 above), and a drain D with a drain voltage V_{D}. A gate driver 642 (e.g., gate driver 192 above) has an output 643 that provides a gate drive voltage signal V_{G} (e.g., the gate voltage) to the gate G and is powered by a gate drive supply with a gate drive supply voltage V_{DRV}. The bias circuit 640 includes a clamp circuit configured to provide a field plate bias voltage signal V_{F} to the field plate 641. The clamp circuit in this example includes a capacitor 644 coupled between the field plate 641 and the gate G of the transistor T, as well as a reset circuit 645 (e.g., a switch) connected in parallel with the capacitor 644 to reset the field plate 641 to the gate voltage V_{G}, where the reset circuit is configured to close after the gate G is turned on and the reset circuit 645 is configured to open before the gate G turns off.

Referring now to FIGS. 6F and 6G, FIG. 6F shows an example active source shunt bias circuit 650 for a drain extended transistor T with a source S, a gate G, a single field plate 651 (e.g., field plate 142 in FIG. 1 above), and a drain D with a drain voltage V_{D}. A gate driver 652 (e.g., gate driver 192 above) has an output 653 that provides a gate drive voltage signal V_{G} (e.g., the gate voltage) to the gate G and is powered by a gate drive supply with a gate drive supply voltage V_{DRV}. The bias circuit 650 includes a clamp circuit configured to provide a field plate bias voltage signal V_{F} to the field plate 651. The clamp circuit in this example includes a capacitor 654 with a capacitance C_{SHUNT} coupled between the field plate 651 and the source S of the transistor T. The clamp circuit includes a reset circuit 655 (e.g., switches) with a first reset switch RESET1 connected between the field plate 651 and the gate drive supply, as well as a second reset switch RESET2 connected between the field plate 651 and the source S of the transistor T in parallel with the capacitor 654.

FIG. 6G shows a graph 657 with curves representing the drain voltage V_{D}, the field plate bias voltage signal V_{F}, and the gate drive voltage signal V_{G} with respect to the voltage V_{S} of the source S of the transistor T in FIG. 6F. The graph 657 shows one example excursion of the transistor drain-source voltage (V_{DS}) from zero to a maximal value (e.g., a rated breakdown voltage of the transistor T), and then back to zero during operation of the bias circuit 650 while the gate driver 652 transitions the gate voltage V_{G} low while the drain voltage V_{D} is at the maximal value. The field plate bias voltage signal V_{F} in this example starts at approximately zero and rises during the upward excursion of the drain voltage V_{D} to a steady-state value V_{F}. In one example, the reset circuit 655 is controlled to hold the first reset switch RESET1 closed to initialize the field plate bias voltage signal V_{F} to the gate drive supply voltage V_{DRV} when V_{D} is near 0 V (e.g., by monitoring V_{DS} or V_{G}), and then the first reset switch RESET1 is opened (curve 658 goes low in the graph 657 of FIG. 6G) to disconnect the capacitor 654 from the gate drive supply voltage V_{DRV}. The reset control circuitry (not shown) in this example then briefly closes the second reset switch RESET2 (curve 659 in FIG. 6G) to discharge the capacitor and reset the field plate bias voltage signal V_{F} to 0 V with respect to the source S of the transistor T, after which the second reset switch RESET2 is again opened. This example allows the field plate bias voltage signal V_{F} to be approximately at the gate drive supply voltage V_{DRV} when the transistor T is in the on state while using a smaller capacitor 654 with less capacitance C_{SHUNT} compared to a reset to V_{DRV} approach, with the first reset switch RESET1 driving V_{F} to V_{DRV} and the second reset switch RESET2 switch resetting V_{F} to 0 V just prior to ramping down the gate voltage V_{G}. When V_{G} is low, both reset switches are open and V_{F} is guided via the capacitor 654.

FIG. 6H shows an example capacitive shunt current source pull-down bias circuit 660 with a drain clamp for a drain extended transistor T with a source S, a gate G, a single field plate 661 (e.g., field plate 142 in FIG. 1 above), and a drain D with a drain voltage V_{D}. A gate driver 662 has an output 663 that provides a gate drive voltage signal V_{G} (e.g., the gate voltage) to the gate G. The bias circuit 660 has a clamp circuit 665 coupled to the drain D and the field plate 661. The clamp circuit 665 includes a junction diode 667 with an anode coupled to drain D and a cathode, as well as a Zener diode 668. The cathode of the junction diode 667 is connected to a cathode of the Zener diode 668, and the anode of the Zener diode 668 is connected to the field plate 661. The bias circuit 660 also includes a capacitor 664 with a capacitance C_{SHUNT} and the capacitor 664 is coupled between the field plate 661 and the source S of the transistor. A pulldown circuit 669 is coupled between the field plate 661 and the source S and may include reset circuitry (e.g., a switch) that is coupled between the field plate 661 and the source S. In another implementation, the reset switch can be omitted. In one implementation, the pulldown circuit 669 has a pulldown resistor with a first terminal coupled to the field plate 661 and a second terminal coupled to the source S. In another implementation, the pulldown circuit 669 includes a current source coupled between the field plate 661 and the source S. The clamp circuit 665 is configured to provide a field plate bias voltage signal V_{F} to the field plate 661. In one example, the capacitance C_{SHUNT} of the capacitor 664 is greater than or equal to a target capacitance of the field plate 661 at 0 V, such that as C_{SHUNT} approaches infinity, the field plate bias voltage V_{F} remains stable.

FIG. 6I shows an example capacitive source shunt current pull up bias circuit 670 with a source clamp for a drain extended transistor T with a source S, a gate G, a single field plate 671 (e.g., field plate 142 in FIG. 1 above), and a drain D with a drain voltage V_{D}. A gate driver 672 has an output 673 that provides a gate drive voltage signal V_{G} (e.g., the gate voltage) to the gate G. The bias circuit 670 also includes a capacitor 674 with a capacitance C_{SHUNT} and the capacitor 674 is coupled between the field plate 671 and the source S of the transistor. The bias circuit 670 has a clamp circuit 678 with a Zener diode having an anode coupled to the source S and a cathode coupled to the field plate 671. In one example, the clamp circuit 678 has a pull up resistor coupled between the field plate 671 and an input of the semiconductor device with an input voltage V_{IN}. The bias circuit 670 in one example includes a reset circuit 679 with a reset switch coupled between the field plate 671 and the source S. In another example, the reset switch can be omitted. In one implementation, the pull up resistor can be omitted, and the reset circuit 679 includes a current source coupled between the field plate 671 and the semiconductor device input having the input voltage V_{IN}. The clamp circuit 678 is configured to provide a field plate bias voltage signal V_{F} to the field plate 671. In one example, the capacitance C_{SHUNT} of the capacitor 674 is greater than or equal to a target capacitance of the field plate 671 at 0 V, such that as C_{SHUNT} approaches infinity, the field plate bias voltage V_{F} remains stable.

FIG. 6J shows a bias circuit 680 with a series or stacked arrangement of clamp capacitors 684 with a reset circuit 685 for active drain shunt field plate stacked clamping for a drain extended transistor T with a source S, a gate G (e.g., also labeled 683), multiple field plates 681, and a drain D with a drain voltage V_{D}. A first clamp capacitor 684 has a first (e.g., lower) terminal coupled to a bottom reference node with a voltage V_{BOT} and a second terminal coupled to a first field plate 681 with a first field plate bias voltage V_{F1}. In one example, the bottom reference node can be the source S of the transistor T. In other implementations, the bottom reference node can be coupled to a different circuit node, such as the gate 683, a gate driver supply node (not shown), an input node of the semiconductor device, etc. The remaining clamp capacitors 684 are coupled between a respective one of the field plates 681 and a previous field plate 681 to control the respective field plate bias voltages V_{F1}, V_{F2}, . . . , V_{Fn}. The reset circuit 685 includes reset switches that are activated in unison according to a reset signal RESET, with each reset switch coupled between a corresponding one of the field plates 681 and an associated row reference voltage node with respective reference voltages V_{R1}, V_{R2}, . . . , V_{Rn}.

FIG. 6K shows a capacitive source shunt bias circuit 690 with parallel clamp capacitors 694 for biasing multiple field plates 691 of a drain extended transistor T (e.g., FIG. 2 above) with a source S, a gate G (e.g., also labeled 693), field plates 691, and a drain D with a drain voltage V_{D}. The bias circuit 690 includes clamp capacitors 694 coupled to a respective field plate 691 and a respective bottom reference node 696, as well as a reset circuit with reset switches coupled between each of the respective field plate 691 and an associated reset reference node. The first capacitor 694 is coupled between the first field plate 691 with a first field plate voltage V_{F1} and a first bottom reference node 696 having a first bottom reference voltage V_{BOT1}. A first reset switch is coupled between the first field plate 691 and a first reset reference node 697 with a first reference voltage V_{R1}. The second capacitor 694 is coupled between the second field plate 691 with a second field plate voltage V_{F2} and a second bottom reference node 696 having a second bottom reference voltage V_{BOT2}. A second reset switch is coupled between the second field plate 692 and a second reset reference node 697 with a second reference voltage V_{R2}. Any further field plates 691 are similarly connected to corresponding capacitor 694 and reset switches of the bias circuit 690, with a final or n^{th} capacitor 694 coupled between the n^{th} field plate 691 with an n^{th} field plate voltage V_{Fn} and an n^{th} bottom reference node 696 having an n^{th} bottom reference voltage V_{BOTn}. An n^{th} reset switch is coupled between the n^{th} field plate 692 and an n^{th} reset reference node 697 with a reset reference voltage V_{Rn}.

In one implementation, the bottom reference nodes 696 are coupled together at the source S of the transistor T In another implementation, the bottom reference nodes 696 are coupled together at another suitable circuit node, such as the gate 693, a gate driver supply node (not shown), an input node of the semiconductor device, etc. In yet another implementation, the bottom reference nodes 696 are coupled to individual reference nodes having different reference node voltages, for example, where V_{BOT1}<V_{BOT2} . . . , <V_{BOTn}. In certain implementations, the reset reference nodes 697 can be coupled together at a suitable circuit node, such as a gate driver circuit (not shown), or to another suitable circuit node where the reset reference voltages V_{R1}=V_{Rn} . . . , =V_{Rn}. In other implementations, the reset reference nodes 697 can have different reference node voltages, for example, where V_{R1}<V_{R2} . . . , <V_{Rn}. Any suitable combination of connections for the bottom nodes 696 and the reset reference nodes 697 can be used, for example, such that the bias voltages of the field plates 691 have monotonically increasing voltage values in the direction from the source S to the drain D (e.g., V_{F1}<V_{F2}<. . . , V_{Fn}).

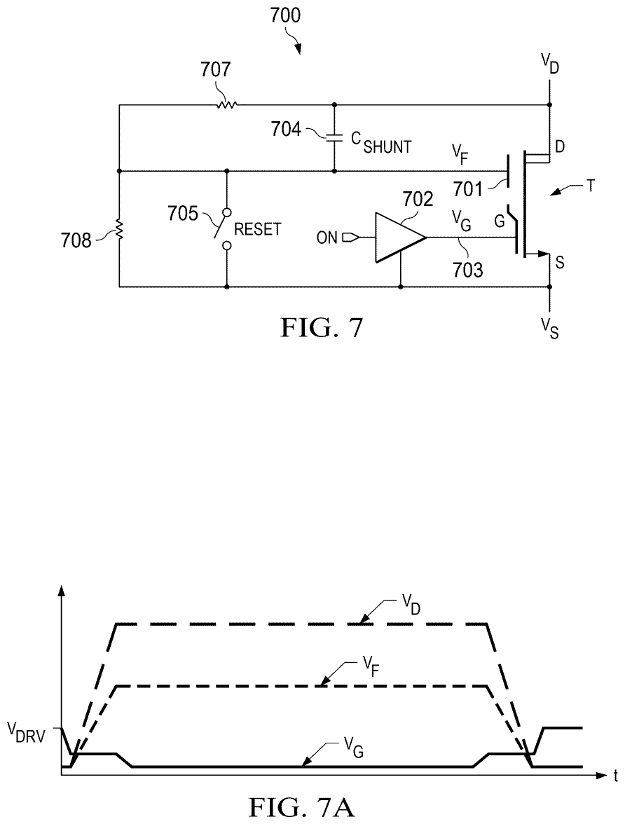

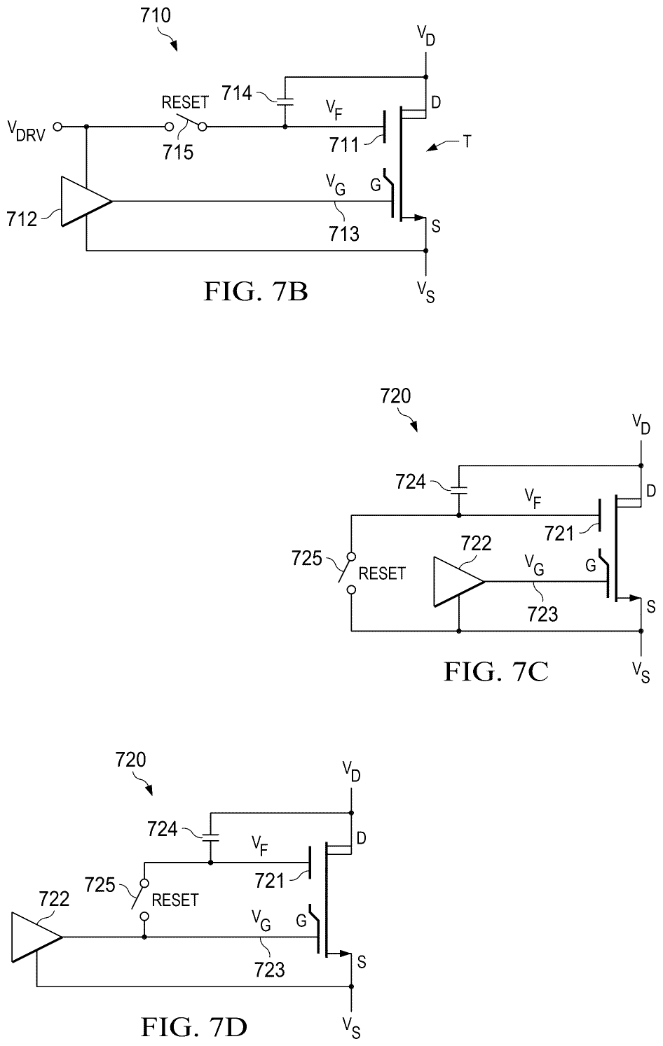

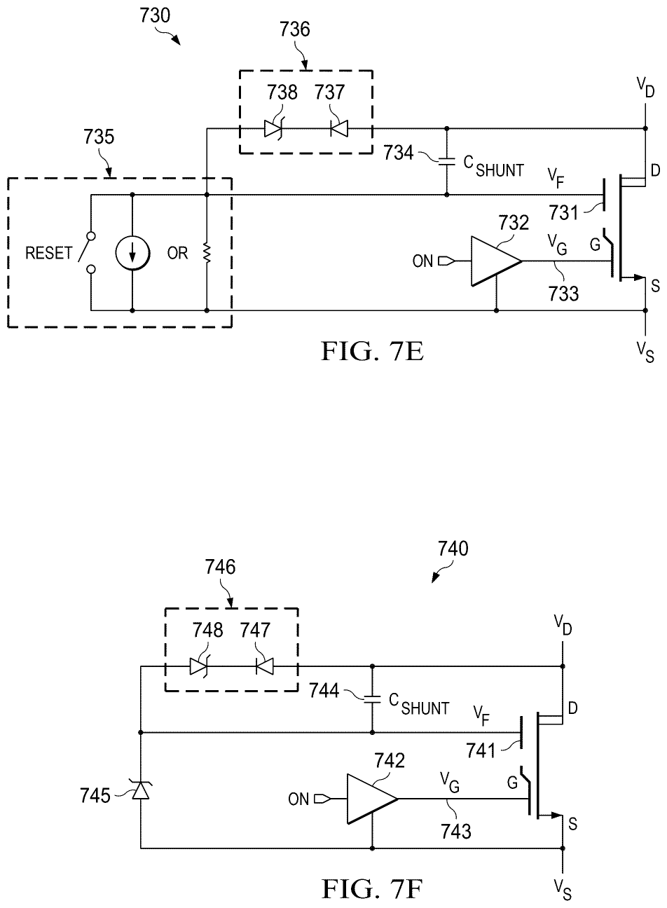

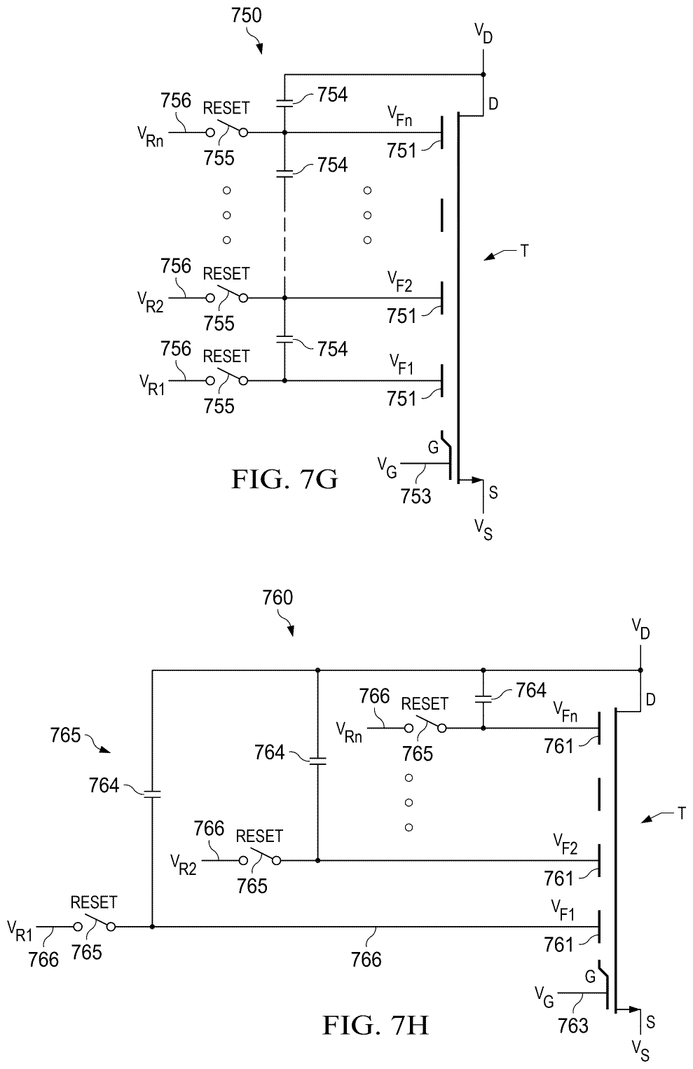

Referring also to FIGS. 7-7H, further examples provide capacitive drain shunt configurations for biasing one or more field plates of a drain extended transistor T with a source S, a gate G, one or more field plates (e.g., field plate 142 in FIG. 1 above), and a drain D with a drain voltage V_{D}. In one or more examples, the bias circuit is coupled to the field plate or field plates and includes a reset circuit operated by suitable control circuitry (not shown) for coordinated timing with respect to actuation of the transistor gate G. In these or other examples, the bias circuit includes one or more capacitors. In these or other examples, the bias circuit can include a pull up circuit with a resistor or a current source coupled to the drain D. In these or other examples, the bias circuit can include a pulldown circuit with a resistor or current source coupled to a source S of the drain extended transistor T or a resistor divider circuit.

FIG. 7 shows an example active drain shunt bias circuit 700 for a drain extended transistor T with a source S, a gate G, a single field plate 701 (e.g., field plate 142 in FIG. 1 above), and a drain D with a drain voltage V_{D}. A gate driver 702 (e.g., gate driver 192 above) has an output 703 that provides a gate drive voltage signal V_{G} (e.g., the gate voltage) to the gate G. The bias circuit 700 includes a drain shunt circuit configured to provide a field plate bias voltage signal V_{F} to the field plate 701. The drain shunt circuit in this example includes a capacitor 704 coupled between the field plate 701 and the drain D of the transistor T, as well as a reset circuit 705 (e.g., a switch) connected between the field plate 701 and the source S of the transistor T. The bias circuit 700 also includes a resistor divider with a first resistor 707 having a first terminal coupled to the drain D and a second terminal coupled to the field plate 701, as well as a second resistor 708 with a first terminal coupled to the field plate 701 and a second terminal coupled to the source S of the transistor T in parallel with the reset circuit 705. In one example, the reset circuit 705 is controlled in a synchronized fashion with respect to the gate driver 702, for example, to close (e.g., connect the field plate 701 to the source S) in a fixed temporal relationship with respect to a gate driver signal that turns the transistor T on, and then opens the reset circuit 705 to allow the capacitor 704 to charge at a fixed temporal relationship to a gate drive signal that turns the transistor T off.

FIG. 7A shows a graph with curves representing the drain voltage V_{D}, the field plate bias voltage signal V_{F}, and the gate drive voltage signal V_{G} with respect to the voltage V_{S} of the source S during one excursion of the transistor drain-source voltage (V_{DS}) from zero to a maximal value (e.g., a rated breakdown voltage of the transistor T), and then back to zero during operation of the bias circuit 700 while the gate driver 702 transitions the gate voltage V_{G} low while the drain voltage V_{D} is at the maximal value. The field plate bias voltage signal V_{F} in this example starts at approximately zero and rises during the upward excursion of the drain voltage V_{D} to a target value V_{F}.

In one example, the reset circuit 705 in FIG. 7 is controlled to initialize the field plate bias voltage signal V_{F} to 0 V when V_{D} is near 0 V (e.g., by monitoring V_{DS} or V_{G}). The capacitance C_{SHUNT} of the capacitor 704 can be chosen such that transition of V_{DS} from 0 V to a rated breakdown voltage V_{BV} translates the field plate 701 from 0V to a target field plate bias voltage V_{F}, and the capacitor 704 can be created using metal system of the semiconductor device or any suitable technique. In other implementations, the field plate 701 can alternatively be reset to another voltage, such as V_{S}, V_{G}, or another supply (e.g., referred to V_{S}) with any suitable corresponding change to the capacitance C_{SHUNT}. In these or other implementations, the reset circuit 705 can be omitted, for example, if the resistor divider (e.g., resistors 707 and 708) is well matched such that when V_{DS}=a rated breakdown voltage V_{BV}, V_{FS}=V_{FS(TARGET)}. Alternative topologies are possible, for example, hybrid active and capacitive with reset circuit closed after the gate G is turned on and the reset circuit 705 opened before the gate G turns off.

FIG. 7B shows an example capacitive drain shunt bias circuit 710 for a drain extended transistor T with a source S, a gate G, a single field plate 711 (e.g., field plate 142 in FIG. 1 above), and a drain D with a drain voltage V_{D}. A gate driver 712 (e.g., gate driver 192 above) has an output 713 that provides a gate drive voltage signal V_{G} (e.g., the gate voltage) to the gate G and is powered by a gate drive supply with a gate drive supply voltage V_{DRV}. The bias circuit 710 includes a drain shunt capacitor 714 configured to provide a field plate bias voltage signal V_{F} to the field plate 711. The drain shunt capacitor 714 in this example is coupled between the field plate 711 and the drain D of the transistor T. A reset circuit 715 (e.g., a switch) is connected between the field plate 711 and the gate drive supply to reset the field plate 711 to a gate drive voltage V_{DRV}, where the reset circuit is configured to close after the gate G is turned on and the reset circuit 715 is configured to open before the gate G turns off.

FIG. 7C shows an example capacitive drain shunt bias circuit 720 for a drain extended transistor T with a source S, a gate G, a single field plate 721 (e.g., field plate 142 in FIG. 1 above), and a drain D with a drain voltage V_{D}. A gate driver 722 (e.g., gate driver 192 above) has an output 723 that provides a gate drive voltage signal V_{G} (e.g., the gate voltage) to the gate G. The bias circuit 720 includes a drain shunt capacitor 724 configured to provide a field plate bias voltage signal V_{F} to the field plate 721. The drain shunt capacitor 724 in this example is coupled between the field plate 721 and the drain D of the transistor T. A reset circuit 725 (e.g., a switch) is connected between the field plate 721 and the source S to reset the field plate 721 to 0 V, where the reset circuit is configured to close after the gate G is turned on and the reset circuit 725 is configured to open before the gate G turns off.

FIG. 7D shows another example implementation of the capacitive drain shunt bias circuit 720 for the drain extended transistor T with a source S, a gate G, a single field plate 721 (e.g., field plate 142 in FIG. 1 above), and a drain D with a drain voltage V_{D}. The gate driver 722 (e.g., gate driver 192 above) has an output 723 that provides a gate drive voltage signal V_{G} (e.g., the gate voltage) to the gate G. The bias circuit 720 in this example includes the drain shunt capacitor 724 configured to provide the field plate bias voltage signal V_{F} to the field plate 721. The drain shunt capacitor 724 is coupled between the field plate 721 and the drain D of the transistor T. A reset circuit 725 (e.g., a switch) in this example is connected between the field plate 721 and the gate G to reset the field plate 721 to the gate voltage V_{G}, where the reset circuit is configured to close after the gate G is turned on and the reset circuit 725 is configured to open before the gate G turns off.

FIG. 7E shows an example capacitive drain shunt pull-down bias circuit 730 with a drain shunt capacitor 734 for a drain extended transistor T with a source S, a gate G, a single field plate 731 (e.g., field plate 142 in FIG. 1 above), and a drain D with a drain voltage V_{D}. A gate driver 732 has an output 733 that provides a gate drive voltage signal V_{G} (e.g., the gate voltage) to the gate G. The bias circuit 730 has a clamp circuit 736 coupled to the drain D and the field plate 731. The clamp circuit 736 includes a junction diode 737 with an anode coupled to drain D and a cathode, as well as a Zener diode 738. The cathode of the junction diode 737 is connected to a cathode of the Zener diode 738, and the anode of the Zener diode 738 is connected to the field plate 731. The bias circuit 730 also includes the drain shunt capacitor 734 with a capacitance C_{SHUNT} and the capacitor 734 is coupled between the field plate 731 and the drain D of the transistor. A pulldown circuit 735 is coupled between the field plate 731 and the source S and may include reset circuitry (e.g., a reset switch) that is coupled between the field plate 731 and the source S. In another implementation, the reset switch can be omitted. In one implementation, the pulldown circuit 735 has a pulldown resistor with a first terminal coupled to the field plate 731 and a second terminal coupled to the source S. In another implementation, the pulldown circuit 735 includes a current source coupled between the field plate 731 and the source S. The clamp circuit 736 is configured to provide a field plate bias voltage signal V_{F} to the field plate 731.

FIG. 7F shows an example capacitive drain and source shunt bias circuit 740 with a drain shunt capacitor 744 for a drain extended transistor T with a source S, a gate G, a single field plate 741 (e.g., field plate 142 in FIG. 1 above), and a drain D with a drain voltage V_{D}. A gate driver 742 has an output 743 that provides a gate drive voltage signal V_{G} (e.g., the gate voltage) to the gate G. The bias circuit 740 has a clamp circuit 746 coupled to the drain D and the field plate 741. The clamp circuit 746 includes a junction diode 747 with an anode coupled to drain D and a cathode, as well as a Zener diode 748. The cathode of the junction diode 747 is connected to a cathode of the Zener diode 748, and the anode of the Zener diode 748 is connected to the field plate 741. The bias circuit 740 also includes a drain shunt capacitor 744 with a capacitance C_{SHUNT} and the capacitor 744 is coupled between the field plate 741 and the drain D of the transistor. A second Zener diode 745 has a cathode coupled to the field plate 741 and an anode coupled to the source S. The clamp circuit 746 is configured to provide a field plate bias voltage signal V_{F} to the field plate 741.

FIG. 7G shows a bias circuit 750 with a series or stacked arrangement of shunt capacitors 754 with a reset circuit 755 for active drain shunt field plate stacked clamping for a drain extended transistor T with a source S, a gate G (e.g., also labeled 753), multiple field plates 751, and a drain D with a drain voltage V_{D}. A first drain shunt capacitor 754 has a first (e.g., lower) terminal coupled to the first field plate 751 with a voltage V_{F1} and a second terminal coupled to the second field plate 751 with a higher second field plate bias voltage V_{F2}. A reset circuit 755 includes reset switches coupled between each of the field plate 751 and a respective reset reference node 756, including a first reset switch connected between the first field plate 751 and a first reset reference node 756. The remaining drain shunt capacitors 754 are coupled between a respective one of the field plates 751 and a subsequent field plate 751 to control the respective field plate bias voltages V_{F1}, V_{F2}, . . . , V_{Fn}, and a final reset capacitor 754 is coupled between the final field plate 751 (with field plate bias voltage V_{Fn}) and the drain D. The reset circuit 755 includes reset switches that are activated in unison according to a reset signal RESET, with each reset switch coupled between a corresponding one of the field plates 751 and an associated row reference voltage node with respective reference voltages V_{R1}, V_{R2}, . . . , V_{Rn}. In one example, the reset reference nodes 756 are connected to corresponding tap nodes of a resistor voltage divider (not shown) that is coupled between the drain D and the source S of the transistor T. In this or another example, the respective reference voltages are set such that V_{R1}<V_{R2}<. . . , <V_{Rn}, and the bias circuit 750 provides the field plate bias voltages such that V_{F1}<V_{F2}<. . . , V_{Fn}.

FIG. 7H shows another multiple biased field plate example with a capacitive drain shunt bias circuit 760 having clamp capacitors 764 for biasing multiple field plates 761 of a drain extended transistor T (e.g., FIG. 2 above) with a source S, a gate G (e.g., also labeled 763), field plates 761, and a drain D with a drain voltage V_{D}. The bias circuit 760 includes drain shunt capacitors 764 coupled between the drain D and a respective field plate 761, as well as a reset circuit with reset switches 765 coupled between each of the respective field plate 761 and an associated reset reference node 766. The first drain shunt capacitor 764 is coupled between the drain D and the first field plate 761 with a first field plate voltage V_{F1}. A first reset switch 765 is coupled between the first field plate 761 and a first reset reference node 766 with a first reference voltage V_{R1}. The second drain shunt capacitor 764 is coupled between the drain and the second field plate 761 with a second field plate voltage V_{F2}. A second reset switch 765 is coupled between the second field plate 762 and a second reset reference node 766 with a second reference voltage V_{R2}. Any further field plates 761 are similarly connected to corresponding capacitor 764 and reset switches 765 of the bias circuit 760, with a final or n^{th} capacitor 764 coupled between the drain D and the n^{th} field plate 761 with an n^{th} field plate voltage V_{Fn}. An n^{th} reset switch 765 is coupled between the n^{th} field plate 762 and an n^{th} reset reference node 766 with a reset reference voltage V_{Rn}. In one implementation, the reset reference nodes 766 can be coupled together at a suitable circuit node, such as the source S of the transistor T, or to another suitable circuit node where the reset reference voltages V_{R1}=V_{Rn} . . . ,=V_{Rn}. In other implementations, the reset reference nodes 766 can have different reference node voltages, for example, where V_{R1}<V_{R2} . . . , <V_{Rn}, such as by connection to respective tap nodes of a resistor voltage divider (not shown). Any suitable combination of connections for the reset reference nodes 766 can be used, for example, such that the bias voltages of the field plates 761 have monotonically increasing voltage values in the direction from the source S to the drain D (e.g., V_{F1}<V_{F2}<. . . , V_{Fn}).

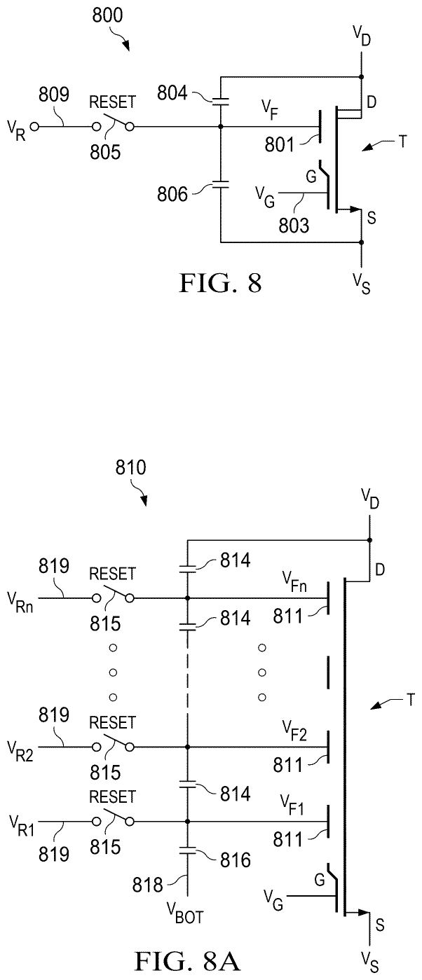

Referring also to FIGS. 8 and 8A, further examples can provide hybrid drain and source shunt bias circuits with reset circuitry for drain extended transistors T having one or more biased field plates. FIG. 8 shows a single biased field plate example with a capacitive source and drain shunt bias circuit 800 having shunt capacitors 804 and 806 for biasing a field plate 801 of a drain extended transistor T with a source S, a gate G (e.g., also labeled 803), a field plate 801, and a drain D with a drain voltage V_{D}. The bias circuit 800 includes a shunt capacitor 804 coupled between the drain D and the field plate 801 and a second shunt capacitor 806 coupled between the field plate 801 and the source S. The bias circuit 800 also includes a reset circuit 805 (e.g., a reset switch) coupled between the field plate 801 and a reset reference node 809 with a reset reference voltage V_{R}. The shunt capacitors 804 and 806 create the field plate voltage V_{F}. Where the shunt capacitors 804 and 806 are of approximately equal capacitance, the field plate voltage V_{F} is approximately V_{DS}/2, and unequal capacitances can be used in order to provide a different field plate voltage V_{F}. The reset reference node 809 can be connected to any suitable circuit node, such as the source S, a gate driver supply node (not shown), a semiconductor device input node (not shown), etc. The reset circuit 805 in one example can be omitted. In one implementation, the reset circuit 805 is actuated in a coordinated fashion for a desired temporal relationship between field plate reset operations and actuation of the transistor gate G.

FIG. 8A shows the multiple field plate drain extended transistor T with a capacitive source and drain shunt bias circuit 810 having shunt capacitors 814. The bias circuit 810 in this example includes a series or stacked arrangement of shunt capacitors 814 with a reset circuit 815 for active drain and source field plate stacked shunting for a drain extended transistor T with a source S, a gate G (e.g., also labeled 813), multiple field plates 811, and a drain D with a drain voltage V_{D}. A first shunt capacitor 814 has a first (e.g., lower) terminal coupled to the first field plate 811 with a voltage V_{F1} and a second terminal coupled to the second field plate 811 with a higher second field plate bias voltage V_{F2}. The remaining shunt capacitors 814 are coupled between a respective one of the field plates 811 and a subsequent field plate 811 to control the respective field plate bias voltages V_{F1}, V_{F2}, . . . , V_{Fn}, and a final reset capacitor 814 is coupled between the final field plate 811 (with field plate bias voltage V_{Fn}) and the drain D. The bottom capacitor 816 is coupled between the first field plate 811 and a bottom reference node 818 having a bottom reference voltage V_{BOT}. The bottom reference node 818 can be connected to any suitable circuit node, such as the source S, a gate driver supply node (not shown), a semiconductor device input node (not shown), etc.

A reset circuit 815 includes reset switches coupled between each of the field plate 811 and a respective reset reference node 819, including a first reset switch connected between the first field plate 811 and a first reset reference node 819. The reset circuit 815 includes reset switches that are activated in unison according to a reset signal RESET, with each reset switch coupled between a corresponding one of the field plates 811 and an associated row reference voltage node with respective reference voltages V_{R1}, V_{R2}, . . . , V_{Rn}. In one example, the reset reference nodes 819 are connected to corresponding tap nodes of a resistor voltage divider (not shown) that is coupled between the drain D and the source S of the transistor T. In this or another example, the respective reference voltages are set such that V_{R1}<V_{R2}<. . . , <V_{Rn}, and the bias circuit 810 provides the field plate bias voltages such that V_{F1}<V_{F2}<. . . , V_{Fn}.

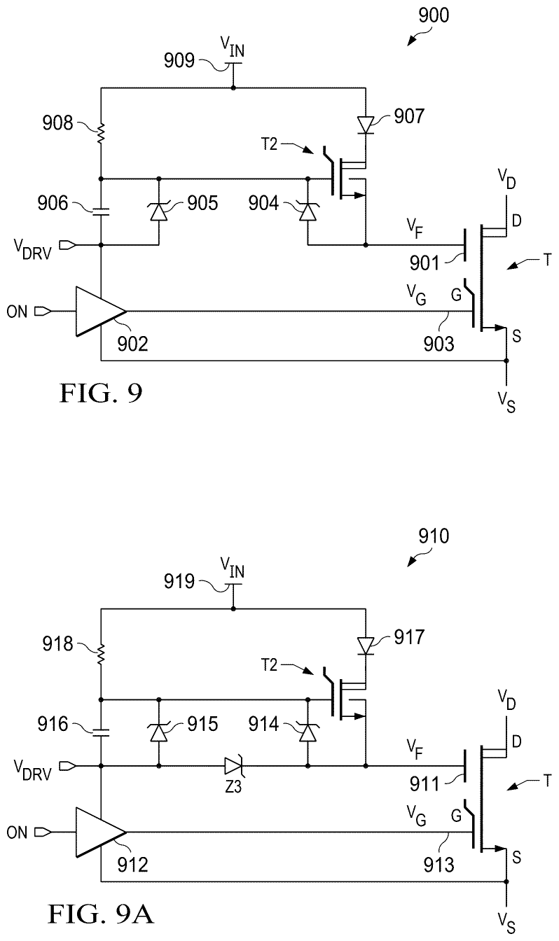

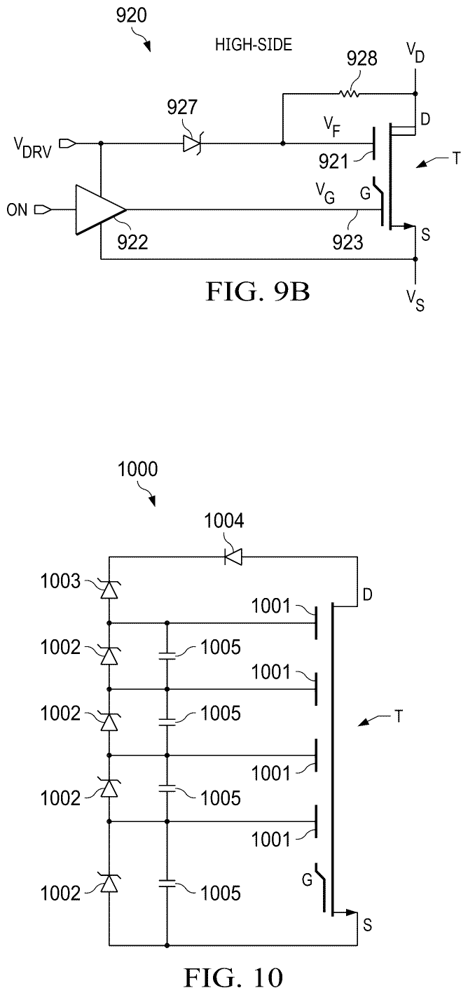

Referring also to FIGS. 9-9B, further examples provide direct drive field place biased circuitry, for example, to facilitate improved specific resistance in a low side switch in transistor application. FIG. 9 shows an active bias circuit 900 for active drain and source shunt field plate stacked clamping for a drain extended transistor T with a source S, a gate G (e.g., also labeled 903), a field plate 901, and a drain D with a drain voltage V_{D}. A gate driver 902 (e.g., gate driver 192 above) has an output 903 that provides a gate drive voltage signal V_{G} (e.g., the gate voltage) to the gate G and is powered by a gate drive supply with a gate drive supply voltage V_{DRV}. The bias circuit 900 includes first and second Zener diodes 904 and 905, respectively, as well as a capacitor 906 connected in parallel with the second Zener diode 905. The bias circuit 900 is an active circuit with a second transistor T2 having a source coupled to the field plate 901, a gate, and a drain coupled to an input node 909 by a diode 907. The first Zener diode 904 has an anode coupled to the field plate 901 and a cathode coupled to the gate of the second transistor T2. The second Zener diode 905 has an anode coupled to the gate drive supply as well as a cathode coupled to the gate of the transistor T2. The capacitor 906 and the cathode of the second Zener diode 905 are coupled to the input node 909 by a resistor 908. Low side operation of the drain extended transistor T (e.g., in a half bridge circuit configuration) is facilitated by the second transistor T2 of the bias circuit 900 which provides a source-follower to pull-up the field plate bias voltage V_{F} of the field plate 901 when the low side transistor T is turned on. The bias circuit 900 can advantageously reduce the on state drain-source resistance (RDSON) of the transistor T, for example, where a 5 V field plate bias voltage V_{F} in one example can provide approximately 10% RDSON reduction, and an 18 V field plate bias voltage V_{F} to provide approximately 20% RDSON reduction compared with a 0 V field plate bias voltage V_{F}. In one example, the Zener diodes 905 can be sized (e.g., Zener voltages) for any desired level of field plate bias voltage V_{F}.

FIG. 9A shows another example active bias circuit 910 for active drain and source shunt field plate stacked clamping for a drain extended transistor T with a source S, a gate G (e.g., also labeled 913), a field plate 911, and a drain D with a drain voltage V_{D}. A gate driver 912 (e.g., gate driver 192 above) has an output 913 that provides a gate drive voltage signal V_{G} (e.g., the gate voltage) to the gate G and is powered by a gate drive supply with a gate drive supply voltage V_{DRV}. The bias circuit 910 includes first and second Zener diodes 914 and 915, respectively, as well as a capacitor 916 connected in parallel with the second Zener diode 915. The bias circuit 910 is an active circuit with a second transistor T2 having a source coupled to the field plate 911, a gate, and a drain coupled to an input node 919 by a diode 917. The first Zener diode 914 has an anode coupled to the field plate 911 and a cathode coupled to the gate of the second transistor T2. The second Zener diode 915 has an anode coupled to the gate drive supply as well as a cathode coupled to the gate of the transistor T2. The bias circuit 910 in FIG. 9A further includes a third Zener diode Z3 having an anode connected to the gate drive supply and a cathode connected to the field plate 911. The capacitor 916 and the cathode of the second Zener diode 915 are coupled to the input node 919 by a resistor 918. Low side operation of the drain extended transistor T (e.g., in a half bridge circuit configuration) is facilitated by the second transistor T2 of the bias circuit 910 which provides a source-follower to pull-up the field plate bias voltage V_{F} of the field plate 911 when the low side transistor T is turned on. The bias circuit 910 can advantageously reduce the on state drain-source resistance (RDSON) of the transistor T to facilitate low side operation in a half bridge circuit (not shown), and the Zener diodes 915 and Z3 can be sized (e.g., Zener voltages) for any desired level of field plate bias voltage V_{F}. In one example, the third Zener diode Z3 can be sized for a desired drain current level of the transistor T, and the first and second Zener diodes 914 and 915 can be smaller than Z3, although close matching between the sizes of the Zener diodes 914, 915 and Z3 may help mitigate source follower leakage in operation.

FIG. 9B shows another example bias circuit 920 that can be used for high side operation of a drain extended transistor T with a source S, a gate G (e.g., also labeled 923), a field plate 921, and a drain D with a drain voltage V_{D}. A gate driver 922 (e.g., gate driver 192 above) has an output 923 that provides a gate drive voltage signal V_{G} (e.g., the gate voltage) to the gate G and is powered by a gate drive supply with a gate drive supply voltage V_{DRV}. The bias circuit 920 includes a clamp circuit with a Zener diode 925 having an anode connected to the gate drive supply and a cathode connected to the field plate 921, and a resistor 928 coupled between the field plate 921 and the drain D. The clamp circuit in this example controls the field plate voltage V_{F} of the field plate 921, and the bias circuit 920 can help improve specific resistance of the transistor T, for example, for high side operation.

FIGS. 10-16 show further example bias circuits for biasing multiple field plates of a drain extended transistor. FIG. 10 shows an example bias circuit 1000 for a drain extended transistor T with a source S, a gate G, multiple field plates 1001, and a drain D with a drain voltage V_{D}. The bias circuit 1000 in this example includes a clamp circuit with a series or stacked arrangement of Zener diodes 1002 and clamp capacitors 1005. A first one of the Zener diodes 1002 has an anode coupled to the source S and a cathode coupled to the first field plate 1001 and is coupled in parallel with the first clamp capacitor 1005. Further pairs of the Zener diode 1002 and clamp capacitor 1005 are connected in parallel with one another between two successive ones of the field plates 1001. A junction diode 1004 has an anode coupled to the transistor drain D and a cathode, and a further Zener diode 1003 has an anode coupled to the final field plate 1001 and a cathode coupled to the cathode of the junction diode 1004. The bias circuit 1000 advantageously facilitates low loss, high-efficiency operation and works at startup.

FIG. 11 shows another example bias circuit 1100 for a drain extended transistor T with a source S, a gate G, multiple field plates 1101, and a drain D with a drain voltage V_{D}. The bias circuit 1100 in this example includes a clamp circuit with a series or stacked arrangement of Zener diodes 1102 and clamp capacitors 1105. A first one of the Zener diodes 1102 has an anode coupled to the source S and a cathode coupled to the first field plate 1101 and is coupled in parallel with the first clamp capacitor 1105. Further pairs of the Zener diode 1102 and clamp capacitor 1105 are connected in parallel with one another between two successive ones of the field plates 1101. A junction diode 1104 has an anode coupled to the transistor drain D and a cathode, and a further Zener diode 1103 has an anode coupled to the final field plate 1101 and a cathode coupled to the cathode of the junction diode 1104. The bias circuit 1100 also includes a further capacitor 1006 connected in parallel with the further Zener diode 1103, as well as reset circuitry including a first set of switches 1107 individually coupled between the cathode of the junction diode 1104 and a respective one of the field plates 1101, as well as a second set of switches individually coupled between a respective one of the field plates 1101 and the parallel combination of the associated Zener diode 1102 and capacitor 1105.

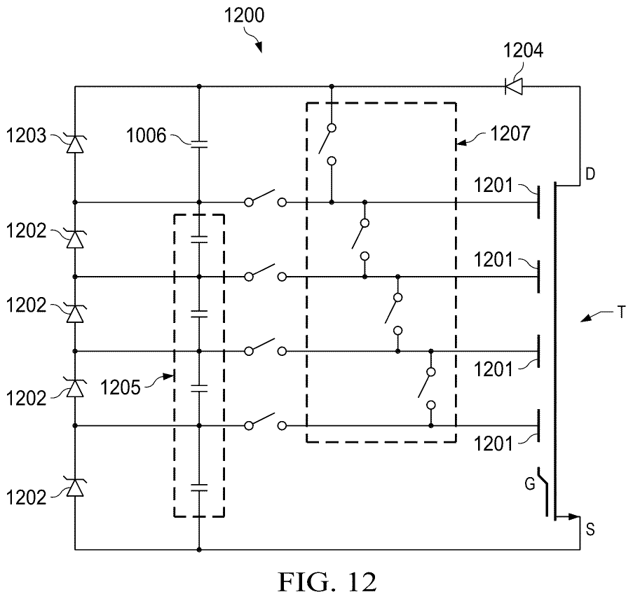

FIG. 12 shows another example bias circuit 1200 for a drain extended transistor T with a source S, a gate G, multiple field plates 1201, and a drain D with a drain voltage V_{D}. The bias circuit 1200 in this example includes a clamp circuit with a series or stacked arrangement of Zener diodes 1202 and clamp capacitors 1205. A first one of the Zener diodes 1202 has an anode coupled to the source S and a cathode coupled to the first field plate 1201 and is coupled in parallel with the first clamp capacitor 1205. Further pairs of the Zener diode 1202 and clamp capacitor 1205 are connected in parallel with one another between two successive ones of the field plates 1201. A junction diode 1204 has an anode coupled to the transistor drain D and a cathode, and a further Zener diode 1203 has an anode coupled to the final field plate 1201 and a cathode coupled to the cathode of the junction diode 1204. The bias circuit 1200 also includes a further capacitor 1006 connected in parallel with the further Zener diode 1203, as well as reset circuitry including a first set of switches 1207 individually coupled between an adjacent pair of the field plates 1201, with a final one of the first set of reset switches 1207 coupled between the final field plate 1201 and the cathode of the junction diode call for. The reset circuitry in this case also includes a second set of switches individually coupled between a respective one of the field plates 1201 and the parallel combination of the associated Zener diode 1202 and capacitor 1205.

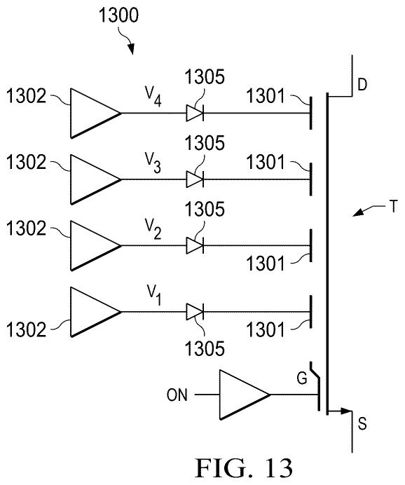

FIG. 13 shows an example active bias circuit 1300 for a drain extended transistor T with a source S, a gate G, multiple field plates 1301, and a drain D with a drain voltage V_{D} without clamp capacitors. The bias circuit 1300 in this example includes driver circuitry with a driver 1302 and a blocking diode 1305 coupled to each of the field plates 1301. For each of the field plates 1301, a driver 1302 provides an associated output voltage (e.g., V₁, V₂, V₃, and V₄ in the illustrated four field plate example). The individual driver outputs are connected to the anode of the respective blocking diode 1305, and the cathode of the diode 1305 is connected to the respective field plate 1301. The drivers 1302 in one example are driven by the drain D of the transistor T by other circuitry (not shown).

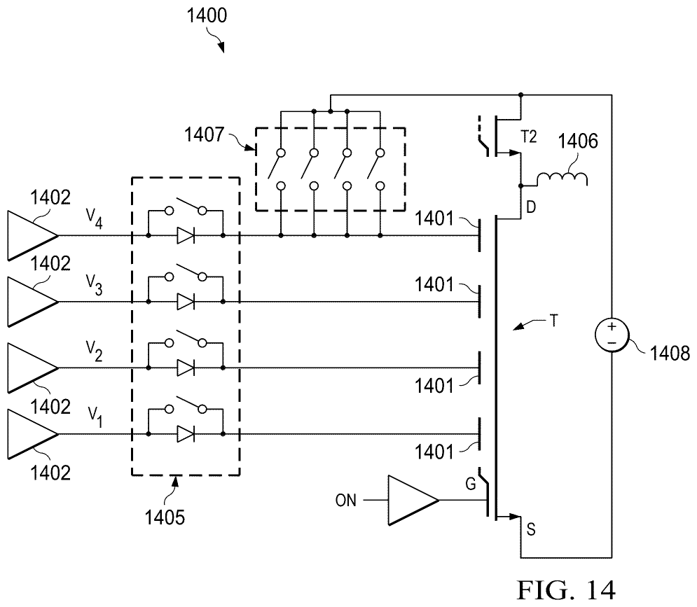

FIG. 14 shows an example active bias circuit 1400 for a drain extended transistor T with a source S, a gate G, multiple field plates 1401, and a drain D with a drain voltage V_{D} without clamp capacitors. The bias circuit 1400 in this example includes driver circuitry with a driver 1402 and a blocking diode 1405 coupled to each of the field plates 1401. For each of the field plates 1401, a driver 1402 provides an associated output voltage (e.g., V₁, V₂, V₃, and V₄ in the illustrated four field plate example), where the driver output voltages are monotonically increasing (e.g., V₁<V₂<V₃<V₄). The individual driver outputs are connected to the anode of the respective blocking diode 1405, and the cathode of the diode 1405 is connected to the respective field plate 1401. The bias circuit 1400 also includes optional reset switches connected in parallel across each of the diode 1405, as well as reset switches 1407 individually connected between a drain of a second transistor T2 and a respective one of the field plates 1401. The bias circuit 1400 in this example further includes an inductor 1406 coupled between a source of the second transistor T2 and the drain D, for example, where the second transistor T2 can be a high side transistor with the drain extended transistor T operating as a low side transistor and a DC-DC power converter configuration using a voltage input (e.g., represented as a voltage source 1408) providing input power to the converter.

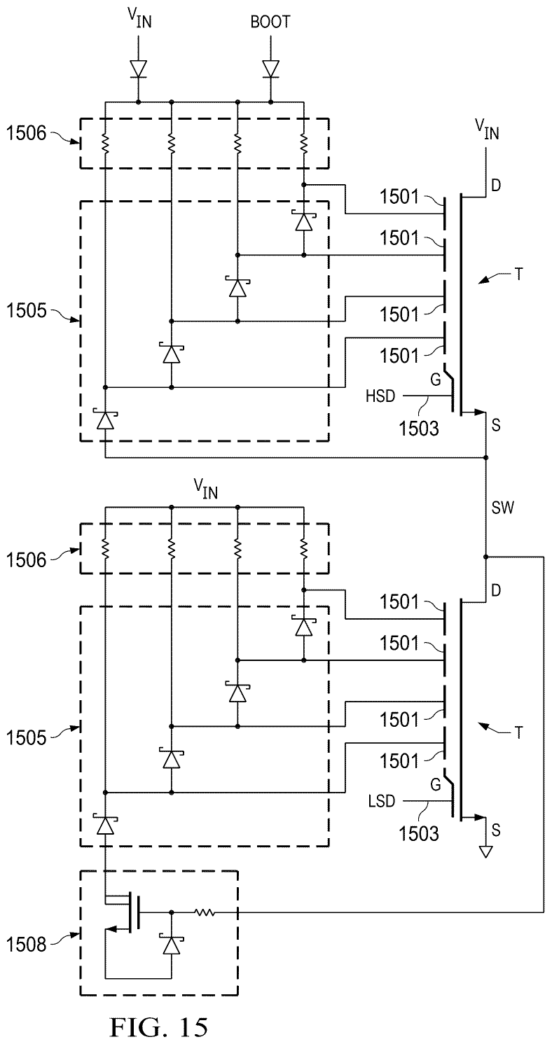

FIG. 15 shows another bias circuit example 1500 without clamp capacitors to provide field plate bias voltage signals to multiple field plates 1501 of drain extended transistors T configured in a half bridge configuration, with a drain D of the upper (e.g., high side) transistor T coupled to an input node with an input voltage VIN, the source S of the upper (e.g., high side) transistor T coupled to a switch node SW, a drain D of the lower (e.g., low side) transistor T coupled to the switch node SW, and the source S of the low side transistor T coupled to a ground or reference node. Each transistor T includes a source S, a gate G (also labeled 1503), multiple field plates 1501, and a drain D with a drain voltage V_{D}. The bias circuitry for each transistor T includes a Zener diode 1505 and a resistor 1506 for each biased field plate 1501. In the illustrated four field plate examples, a Zener diode 1505 is connected between each pair of adjacent ones of the field plates 1501, with an anode coupled to one field plate and a cathode coupled to the next higher field plate 1501, and a bottom Zener diode 1505 has an anode coupled to the source S and a cathode coupled to the first field plate 1501 for the upper transistor T (e.g., high side device). For the lower transistor T, the bottom Zener diode 1505 has an anode coupled to a transistor circuit 1508. The resistors 1506 of the upper transistor T have upper first terminals that are coupled by a first coupling diode to the input node (VIN) and by a second coupling diode to a boot node (BOOT), and the lower or second terminals of the resistors 1506 of the upper transistor T are coupled to a respective one of the field plates 1501. For the lower transistor T, the resistors 1506 are coupled between the input node (VIN) and a respective one of the field plates 1501 of the lower transistor T.

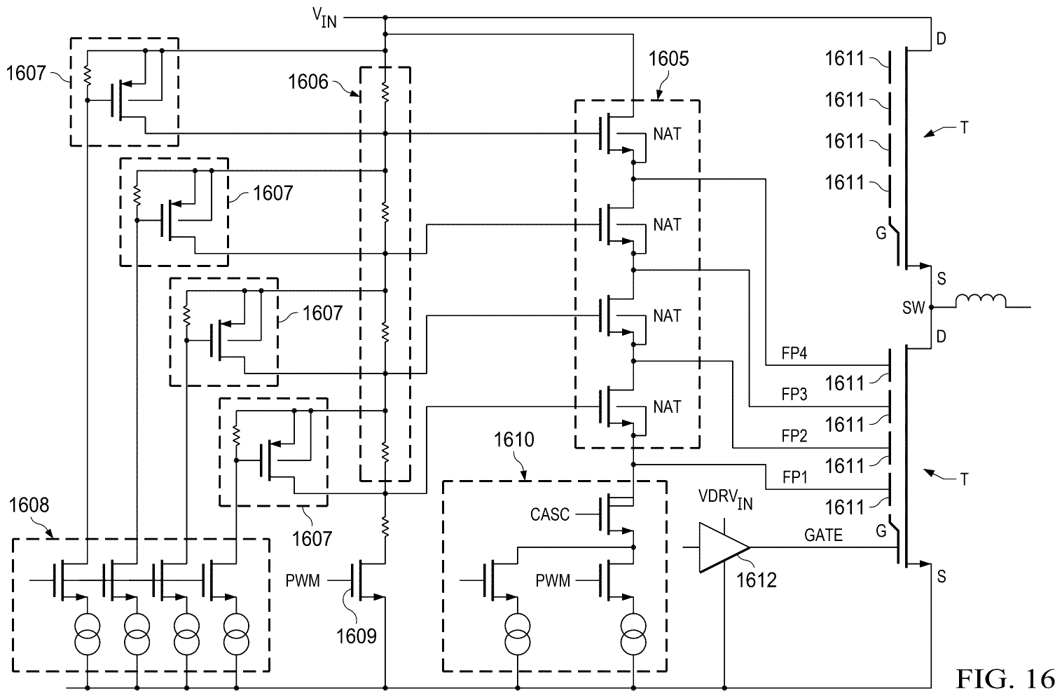

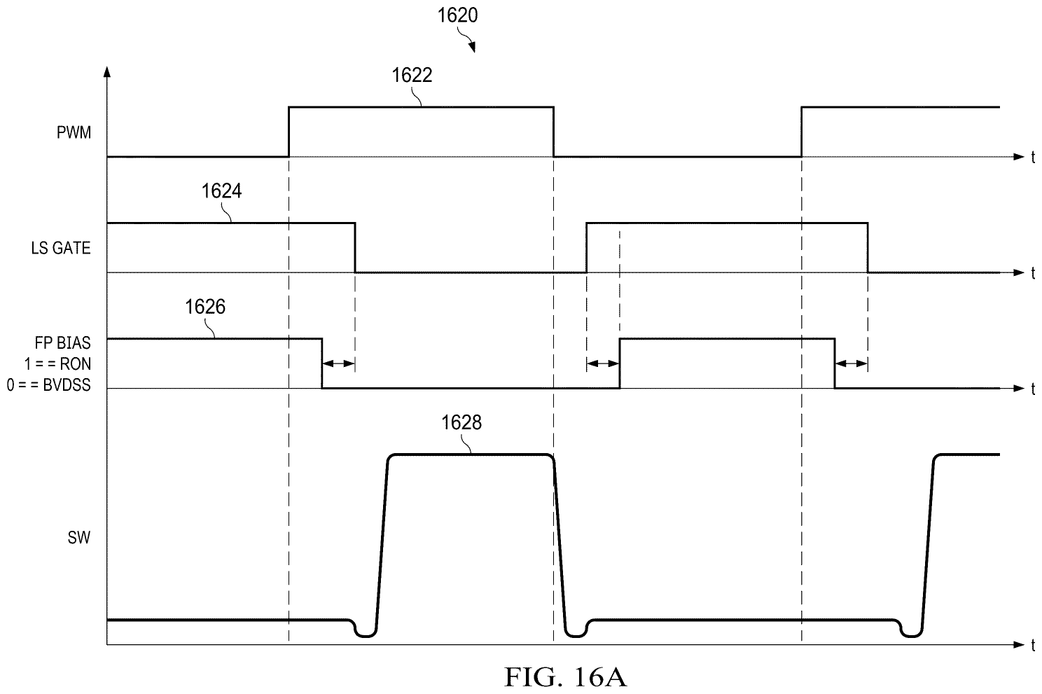

FIGS. 16 and 16A show another example bias circuit without clamp capacitors to provide field plate bias voltage signals to multiple field plates 1611 of drain extended transistors T configured in a half bridge configuration, with a drain D of the upper (e.g., high side) transistor T coupled to an input node with an input voltage VIN, the source S of the upper (e.g., high side) transistor T coupled to a switch node SW, a drain D of the lower (e.g., low side) transistor T coupled to the switch node SW, and the source S of the low side transistor T coupled to a ground or reference node. Each transistor T includes a source S, a gate G (also labeled 1603), multiple field plates 1611, and a drain D with a drain voltage V_{D}. FIG. 16 shows details of the biasing circuitry for the illustrated low side (e.g., lower) transistor T, and the high side (e.g., upper) transistor T can include the same or similar biasing circuitry. The bias circuit has n-channel transistors 1605 coupled between adjacent pairs of the field plates, a resistor divider circuit 1606, and p-channel transistors 1607, as well as a pulse generator circuit 1608 with n-channel transistors and current sources to provide a short on pulse after the low side transistor has turned on to bring the gate voltage up on the source-follower transistors 1605 which drive FP1-FP4 near V_{IN}. The pulse generator 1608 turns on for a short time after the low side transistor has turned on in order to turn on the p-channel transistors 1607. When turned on, the p-channel transistors 1607 will short the resistors of resistor divider 1606 (switch 1609 will be off at this time), thus charging the gates of the n-channel natural transistors 1605 to V_{IN}. Thus, the n-channel natural transistors 1605 will charge FP1 thru FP4 to V_{IN} in order to achieve lowest RDSON on the low side transistor T. The bias circuit of FIG. 16 also includes a pulse width modulated n-channel transistor 1609 coupled between the resistor divider 1606 and a common reference node. In addition, the bias circuit includes a circuit 1610 with n-channel transistors including a first transistor coupled between the first field plate 1611 and a second transistor that is pulse width modulated and coupled to a current source that is connected to the common reference. The source of the first transistor is connected to the drain of a third transistor of the circuit 1610 that is turned on between the pulse width modulated signal of the second transistor going high and the switch node SW going to a maximal value. The example of FIG. 16 also includes a driver 1612 that provides a gate drive signal to the gate G of the transistor T and is powered by a gate driver supply with a gate driver supply voltage VDRV_{IN}.

FIG. 16A shows a graph 1620 with a curve 1622 showing an example pulse width modulation signal applied to the gate of the third transistor of the circuit 1610 in FIG. 16, along with a curve 1624 that shows an example of the low side gate drive signal at the output of the driver 1612, a curve 1626 that shows an example of the field plate bias voltage of one of the field plates 1611 that is high when the low side transistor T is turned on (e.g., low or approximately zero drain-source voltage), and is low when the low side transistor T is turned off. The graph 1620 further shows a curve 1628 with an example of the switch node voltage (SW) in the example half bridge circuit configuration. Curve 1626 indicates the time when the field plate bias voltage is to be at V_{IN} (e.g., when the low side transistor T is in linear region (low or zero drain-source voltage) to enhance RDSON) and when the field plate bias voltage is to be set to the desired values set by the resistor divider network 1606 (e.g., when the low side transistor T is in saturation or in the off state (e.g., large drain-source voltage) to facilitate high BVDSS).

Described examples provide bias circuitry for one or more biased field plates of a drain extended transistor to facilitate drift region electric field profile uniformity, enabling optimally small drift length (limited along the drift region by semiconductor breakdown strength) and hence optimally low on state resistance (limited by the doping density and carrier mobility in the drift region). While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A semiconductor device, comprising:
a drain extended transistor, including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
a field plate between the gate electrode and the drain region; and
a bias circuit including an output coupled to the field plate and a bias input coupled to a gate drive circuit.

2. The semiconductor device of claim 1, further comprising a field relief dielectric layer over the drain drift region, the field relief dielectric layer extending from the gate dielectric layer toward the drain region and having a thickness greater than the gate dielectric layer, wherein the field plate is located over the field relief dielectric layer.

3. A semiconductor device, comprising:
a drain extended transistor, including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
a field plate between the gate electrode and the drain region; and
a bias circuit including a clamp circuit with a diode coupled to the field plate.

4. The semiconductor device of claim 3, wherein the clamp circuit includes a first diode with an anode coupled to the field plate, and a Zener diode with a cathode coupled to a cathode of the first diode.

5. The semiconductor device of claim 3, wherein the clamp circuit includes a Zener diode with a cathode coupled to the field plate.

6. The semiconductor device of claim 3, wherein the clamp circuit includes:
a first terminal;
a second terminal;
a clamp circuit transistor having a drain coupled to the first terminal, a source coupled to the second terminal, and a gate;
a Zener diode having an anode coupled to the gate of the clamp circuit transistor, and a cathode coupled to the first terminal; and
a resistor coupled between the gate of the clamp circuit transistor and the second terminal.

7. A semiconductor device, comprising:
a drain extended transistor, including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
a field plate between the gate electrode and the drain region; and
a bias circuit coupled to the field plate, the bias circuit including a reset circuit.

8. The semiconductor device of claim 7, wherein the bias circuit includes a capacitor.

9. The semiconductor device of claim 7, wherein the bias circuit includes a pull up circuit with a resistor or a current source coupled to the drain region.

10. The semiconductor device of claim 7, wherein the bias circuit includes a pulldown circuit with a resistor or current source coupled to a source of the drain extended transistor.

11. A semiconductor device, comprising:
a drain extended transistor, including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
a field plate between the gate electrode and the drain region; and
a bias circuit coupled to the field plate, the bias circuit including a second transistor.

12. The semiconductor device of claim 11, wherein:
the bias circuit includes a first terminal and a second terminal, the first terminal coupled to the field plate;
the second transistor has a drain coupled to the first terminal, a source coupled to the second terminal, and a gate;
the bias circuit includes a Zener diode having an anode coupled to the gate of the second transistor, and a cathode coupled to the first terminal; and
the bias circuit includes a resistor coupled between the gate of the second transistor and the second terminal.

13. A semiconductor device, comprising:
a drain extended transistor, including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
field plates spaced apart from one another between the gate electrode and the drain region; and
a bias circuit having outputs coupled to the respective field plates, and an input coupled to one of a voltage input of the semiconductor device, the drain region, and a gate drive circuit.

14. The semiconductor device of claim 13, further comprising a field relief dielectric layer over the drain drift region, the field relief dielectric layer extending from the gate dielectric layer toward the drain region and having a thickness greater than the gate dielectric layer, wherein the field plates are located over the field relief dielectric layer.

15. The semiconductor device of claim 13, wherein the input of the bias circuit is coupled to the voltage input of the semiconductor device.

16. The semiconductor device of claim 13, wherein the input of the bias circuit is coupled to the drain region.

17. The semiconductor device of claim 13, wherein the input of the bias circuit is coupled to the gate drive circuit.

18. The semiconductor device of claim 13, wherein the bias circuit is configured to provide a monotonic voltage increase of the field plates from a source of the drain extended transistor to the drain region.

19. A method, comprising:
forming a drain extended transistor in a semiconductor device, the drain extended transistor including:
a semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region; and
a field plate between the gate electrode and the drain region; and
forming a bias circuit in the semiconductor device, the bias circuit including an output coupled to the field plate and a bias input coupled to a gate drive circuit.
